(19) United States
(12) Patent Application Publication
(10) Pub. No.: US 2016/0172514 A1
(43) Pub. Date: Jun. 16, 2016

(54) Photovoltaic Microstructure and Photovoltaic Device Employing Nanowires with Single-Side Conductive Strips

(71) Applicant: Q1 NANOSYSTEMS, EL DORADO HILLS, CA (US)

(72) Inventors: Bob Smith, Placerville, CA (US); John Fisher, El Dorado Hills, CA (US)

(21) Appl. No.: 15/053,251

(22) Filed: Feb. 25, 2016

Related U.S. Application Data
(63) Continuation-in-part of application No. 13/289,979, filed on Nov. 4, 2011.

(51) Int. Cl. H01L 31/0465; H02S 20/32; H01L 31/075

(52) U.S. Cl. CPC H01L 31/0465; H01L 31/075; H02S 20/32

(57) ABSTRACT

A photovoltaic device includes an array of photovoltaically active microstructures each having a generally cylindrical outer periphery and a reflective metal portion on one side thereof. The photovoltaic device is oriented such that the metal portions face away from the sun, reflects light into a respective photovoltaically active microstruture, and provides a conductive path for charge carriers in parallel to an outer conductive layer, which may be a transparent conductive oxide layer. Direction deposition of metal can be employed to form the reflective metal portions.

### RELATED APPLICATIONS

This present application is a continuation-in-part application of U.S. patent application Ser. No. 13/289,979 filed on Nov. 4, 2011, the entire contents of which are incorporated herein by reference.

### FIELD OF INVENTION

This invention pertains generally to photovoltaic microtechnology and more particularly to photovoltaic micro-scale structures.

### BACKGROUND

Solar panels that harness solar energy and convert it to electrical energy are well known. A typical solar electricity system includes the following components: solar panels, charge controller, inverter, and often batteries. A typical solar panel, often referred to as a photovoltaic (PV) module, consists of a one or more interconnected PV cells environmentally sealed in protective packaging consisting of a glass cover and extruded aluminum casing.

The PV cell may be a p-n junction diode capable of generating electricity in the presence of sunlight. It is often made of crystalline silicon (e.g., polycrystalline silicon) doped with elements from either group 13 (group III) or group 15 (group V) on the periodic table. When these dopant atoms are added to the silicon, they take the place of silicon atoms in the crystalline lattice and bond with the neighboring silicon atoms in almost the same way as the silicon atom that was originally there. However, because these dopants do not have the same number of valence electrons as silicon atoms, extra electrons or “holes” become present in the crystal lattice. Upon absorbing a photon that carries an energy that is at least the same as the band gap energy of the silicon, the electrons become free. The electrons and holes freely move around within the solid silicon material, making silicon conductive. The closer the absorption event is to the p-n junction, the greater the mobility of the electron-hole pair.

When a photon that has less energy than silicon's band gap energy strikes the crystalline structure, the electrons and holes are not mobilized. Instead of the photon's energy becoming absorbed by the electrons and holes, the difference between the amount of energy carried by the photon and the band gap energy is converted to heat.

While the idea of converting solar energy to electrical power has much appeal, conventional solar panels have limited usage because their efficiencies are generally only in the range of 15% and are manufactured using costly silicon wafer manufacturing processes and materials. This low efficiency is due in part to the planar configuration of current PV cells, as well as the relatively large distances between the electrodes and the p-n junction. Low efficiency means that larger and heavier arrays are needed to obtain a certain amount of electricity, raising the cost of a solar panel and limiting its use to large-scale structures.

The most common material for solar cells is silicon. Crystalline silicon comes in three categories: single-crystal silicon, polycrystalline silicon, and ribbon silicon. Solar cells made with single or monocrystalline wafers have the highest efficiency of the three, at about 20%. Unfortunately, single crystal cells are expensive and round so they do not completely tile a module. Polycrystalline silicon is made from cast ingots. They are made by filling a large crucible with molten silicon and carefully cooling and solidifying them. The polycrystalline silicon is less expensive than single crystal, but is only about 10-14% efficient depending on the process conditions and resulting imperfections in the material. Ribbon silicon is the last major category of PV grade silicon. It is formed by drawing flat, thin films from molten silicon, and has a polycrystalline structure. Silicon ribbon's efficiency range of 11-13% is also lower than monocrystalline silicon due to more imperfections. Most of these technologies are based on wafers about 300 μm thick. The PV cells are fabricated then soldered together to form a module.

Another technology under development is multijunction solar cells, which is expected to deliver less than 18.5% efficiency in actual use. The process and materials to produce multijunction cells are enormously expensive. Those cells require multiple gallium/indium/arsenide layers. The best is believed to be a sextuple junction cell. Current multijunction cells cannot be made economical for large-scale applications

A promising enabler of PV cells and other technology is microtechnology. However, one problem with implementing microtechnology is that the minute conductors may not be able to withstand their own formation, much less subsequent processing conditions or conditions of use in the end product. For example, the metal forming the microconductors may be soft, making it prone to bending or breaking during application of additional layers.

Further, it has heretofore proven difficult and even impossible to create microarrays having structures of uniform size and/or spacing.

Thus, as alluded to, the technology available to create PV cells and other electronic structures is limited to some extent by processing limitations as well as the sheer fragileness of the structures themselves.

Therefore, it would be desirable to enable creation of microstructures having improved current density and yet are durable enough for practical use in industry.

It would also be desirable to enable fabrication of a solar cell that has a higher than average efficiency, and in some embodiments, higher than about 30%.

### SUMMARY

According to an aspect of the present disclosure, a photovoltaic device is provided. The photovoltaic device includes an array of photovoltaically active microstructures each having a generally cylindrical outer sidewall and arranged in a brush configuration over a substrate. A metal portion is located on a first side of each outer sidewall of the photovoltaically active microstructures. A second side of the each sidewall of the photovoltaically active microstructures is not in physical contact with any metallic material.

According to another aspect of the present disclosure, a method of operating a photovoltaic structure is provided. After the photovoltaic device of the present disclosure is provided, the photovoltaic structure can be rotated with movement of the sun such that the first side of each outer sidewall of the photovoltaically active microstructures faces the sun and the second side of each outer sidewall of the photovoltaically active microstructures faces away from the sun during operation of the photovoltaic structure.

According to yet another aspect of the present disclosure, a method of forming a photovoltaic structure is provided. An array of photovoltaically active microstructures of the present disclosure can be formed on a substrate. A metal can be deposited with directionality onto the array of photovoltaically active microstructures. A direction of deposition of the metal is tilted with respect to a common axial direction of the photovoltaically active microstructures.

A photovoltaic device according to one embodiment includes an array of photovoltaically active microstructures each having a generally cylindrical outer periphery and a dome-shaped tip, each of the microstructures being characterized as absorbing at least 70% of light passing through an outer layer thereof.

A photovoltaic device according to another embodiment includes an array of photovoltaically active microstructures each having a generally cylindrical outer periphery, each microstructure comprising a first photovoltaic layer over a core, and a second photovoltaic layer over the first photovoltaic layer thereby forming a photovoltaically active junction, wherein an outer conductive layer is positioned over the second photovoltaic layer, wherein an index of refraction of the outer conductive layer is less than an index of refraction of the second photovoltaic layer, wherein the index of refraction of the second photovoltaic layer is less than an index of refraction of the first photovoltaic layer, each of the microstructures having a domed tip.

Other aspects and advantages of the present invention will become apparent from the following detailed description, which, when taken in conjunction with the drawings, illustrate by way of example the principles of the invention

### BRIEF DESCRIPTION OF THE DRAWINGS

FIG. 1 is a side cross-section of a particular microstructure embodiment.

FIG. 2 is a perspective view of an exemplary solar brush that may be used to implement solar panels with improved efficiency.

FIG. 3 is a top view of the solar brush showing the tops of the microstructures according to one embodiment.

FIG. 4 is a side cross-section of a particular microstructure embodiment.

FIG. 5 is a side cross-section of a particular microstructure embodiment.

FIG. 6 is a side cross-section of a particular microstructure embodiment.

FIG. 7 is a perspective view of an exemplary solar brush that may be used to implement solar panels with improved efficiency.

FIG. 8 is a side cross-section of a particular microstructure embodiment.

FIG. 9 is a side cross-section of a particular microstructure embodiment.

FIG. 10A is a perspective view of a microstructure with a reflective coating according to one embodiment.

FIG. 10B is a perspective view of a microstructure with a reflective coating according to one embodiment.

FIG. 11A is a vertical cross-sectional view of a first exemplary structure including an array of photovoltaically active microstructures and reflective metal portions according to an embodiment of the present disclosure.

FIG. 11B is a vertical cross-sectional view of a second exemplary structure including an array of photovoltaically active microstructures and reflective metal portions according to an embodiment of the present disclosure.

FIG. 12 is a perspective view of an array of photovoltaically active microstructures with reflective portions thereupon according to an embodiment of the present disclosure.

FIG. 13A is a top-down view of a first configuration of the array of photovoltaically active microstructures with reflective metal portions according to an embodiment of the present disclosure.

FIG. 13B is a top-down view of a second configuration of the array of photovoltaically active microstructures with reflective metal portions according to an embodiment of the present disclosure.

FIG. 13C is a top-down view of a third configuration of the array of photovoltaically active microstructures with reflective metal portions according to an embodiment of the present disclosure.

FIG. 14A illustrates a side view and two horizontal cross-sectional views of a photovoltaically active microstructure and a first exemplary reflective metal portion thereupon according to an embodiment of the present disclosure.

FIG. 14B is a side view and a horizontal cross-sectional view of a photovoltaically active microstructure and a second exemplary reflective metal portion thereupon according to an embodiment of the present disclosure.

FIG. 15A is a vertical cross-sectional view of a third exemplary structure including an array of photovoltaically active microstructures and reflective metal portions according to an embodiment of the present disclosure.

FIG. 15B is a vertical cross-sectional view of a fourth exemplary structure including an array of photovoltaically active microstructures and reflective metal portions according to an embodiment of the present disclosure.

FIG. 16 is an exemplary installation of multiple arrays of photovoltaically active microstructures with reflective metal portions as installed on a frame according to an embodiment of the present disclosure.

### DETAILED DESCRIPTION

The following description is made for the purpose of illustrating the general principles of the present invention and is not meant to limit the inventive concepts claimed herein. Further, particular features described herein can be used in combination with other described features in each and any of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

Various embodiments of the invention are described herein in the context of solar cells. However, it is to be understood that the particular application provided herein is just an exemplary application, and the microcable arrangements of the various embodiments of the present invention are not limited to the application or the embodiments disclosed herein.

This disclosure also relates to micro arrays of thin film solar cells. Solar modules constructed using thin film systems tend to use a single larger single plane thin films solar cell, rather than an array of smaller interconnected micro-scale solar cells. The entire module can use a laser scribe to mark individual cells. It is important to note that micro systems may be processed differently than current technology thin films. Four main thin film material system types are amorphous silicon (A-Si), copper indium selenide (CuInSe₂ commonly referred to as CIS), copper indium gallium selenide (CuInₓGa₁₋ₓSeₓ) commonly referred to as CIGS), and CdTe/CdS. A-Si films are typically fabricated using plasma enhanced chemical vapor deposition (PE-CVD).

The term “microcable” denotes any elongated body whose one dimension (e.g. diameter or width) is of nano or micro scale or size and the other dimension is larger, potentially much larger. A “microstructure” may include one or more microcables. A microcable may be fabricated with dissimilar materials, either as a core rod or wire that is laterally enveloped by one or more layers of material(s), as a microtube that is filled with one or more layers of material(s), as a single structure of one material, etc. Microcables are also referred as microtubes, microrods, microwires, filled microtubes and bristles. The functional element of the microcable in each case is the interface(s) between the two (or more) materials. In various alternative configurations and modes of growth, a succession of layers of different materials, alternating materials or different thicknesses of materials can be deposited to form nested layer microcables.

The term “photovoltaically active p-n junction” denotes any p-n junction with an adequate p-layer and n-layer thickness to generate electricity.

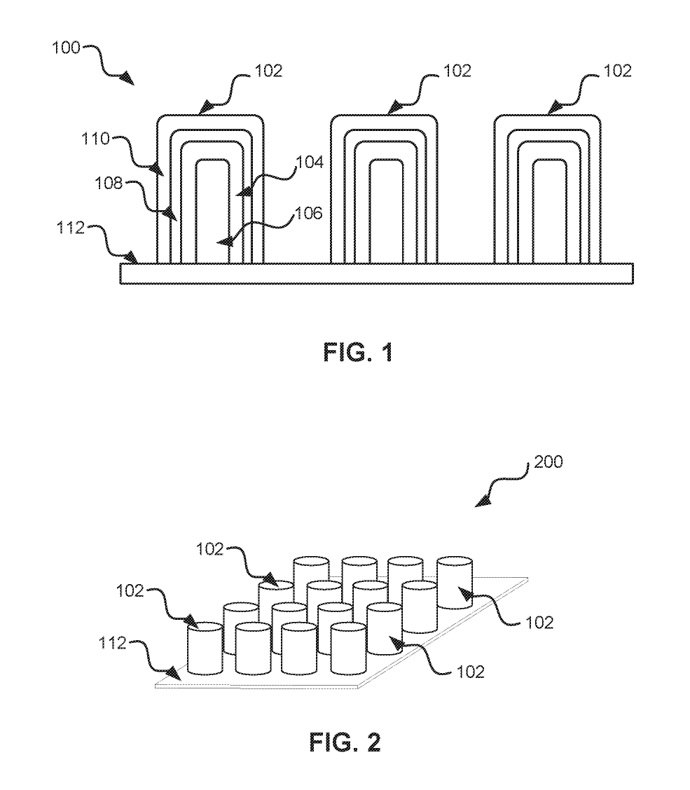

Referring now to FIG. 1, a photovoltaic device 100 has an array of photovoltaically active microstructures 102 is shown in accordance with one embodiment. In one approach, the microstructures may have an average height of between about 0.1 micron and about 50 microns. In a preferred embodiment, the average height may be between about 5 microns and about 30 microns.

Various embodiments may include microstructures of various possible compositions, such as a Si thin film, CdTe/CdS (CdTe/CdS/SnO₂/Indium Tin Oxide(ITO)/glass), GaAs/GaInP, CuInGaSe₂, Cu(InₓGa₁₋ₓ)(S,Se)₂, CuIn₁₋ₓGaₓSe_{1-y}S_{y}, CGSe/CdS, CuInₓGa₁₋ₓTe₂/n-InSe, CdS/CIGS interface, ZnS/CIGS, Cu₂S—CdS, CuInS₂ or a mix of CuₓS, CuInS₂ and CuIn₅S₈, Cu(In,Ga)Se₂/CdS, CIS/In₂Se₃, InN, CIS/In₂Se₃, ZnSₓSe₁₋ₓ. GaInP/GaAs, GaInP/GaAs/Ge, GaAs/CIS, a-Si/CIGS (a-Si is amorphous Si/hydrogen alloy), FeS₂, Cu₂O, ITO/a-CNx (Al Schottky thin-film carbon nitride solar cells), MoS₂ based solar cells, MX2 (M=Mo, W; X=S, Se) thin films with Ni and Cu additives layers, etc. or any other microstructure construction in various embodiments that would be apparent to one of skill in the art upon reading the present description.

In one approach, a photovoltaic device may include a diameter of the core, deposition layer thickness of the photovoltaic layers (in a direction perpendicular to the longitudinal axis of the microstructure), and height of the core and center to center spacing of the core of each microstructure may provide at least 70% absorption of light striking the microstructure, and preferably at least 80% absorption of light striking the microstructure. “Height of the core” in reference to the present approach refers to a direction parallel to the longitudinal axis of the microstructure. Without wishing to be bound by any theory, it is believed that approximately 15-20% of the light is reflected before entering the microstructure.

In still another approach, a diameter of core, deposition layer thickness of the photovoltaic layers of each microstructure provides at least 80% absorption of light for a photovoltaic device. In a preferred embodiment, a diameter, deposition thickness and height of an absorber layer of each microstructure may provide at least 80%, preferably 90%, more preferably 95% and ideally 99% absorption of light for a photovoltaic device. The height is preferably measured in a direction parallel to the longitudinal axis of the microstructure. In addition the height and center to center spacing of the core is of increased importance to the efficiency of the photovoltaic device.

As shown in FIG. 1, the photovoltaically active microstructures 102 in the array 100 each have a generally cylindrical outer periphery. In various embodiments, a photovoltaic device may include but is not limited to a solar cell, solar-powered car, a solar-powered satellite, a solar-powered house, etc. or any other photovoltaic device that may be apparent in various embodiments to one of skill in the art.

Each microstructure 102 includes a first photovoltaic layer 104 over a core 106. In one embodiment, a first photovoltaic layer may be comprised of any photovoltaic material. Examples of photovoltaic materials include, for example, monocrystalline silicon, polycrystalline silicon, amorphous silicon, cadmium telluride, cadmium sulfide, copper indium gallium selenide, etc. or any other photovoltaic material or combination thereof disclosed herein and/or which would become apparent to one of general skill in the art upon reading the present description.

Moreover, in another approach, a core may comprise, but is not limited to, Ni, Cu, Al, Zn, Mo, etc. and alloys of any of the metals with other materials in the list and/or not in the list. In another approach, a core may be a conductive core which may include NiCu, NiPt, NiBi, NiSb, NiAl, and other Ni based alloys, Mo and its alloys, Al and its alloys, etc. In further embodiments, a core may be a pure metallic core formed of any suitable metal and/or its alloys which would become apparent to one of general skill in the art upon reading the present description.

In another approach, a core may be a reflective core (e.g., at least 80% reflective, preferably >85% reflective). The core may be, for example, a metallic microrod, a microrod with an overlying layers (e.g., metal or TCO or metal/TCO or any combination), etc. or any other reflective core which would be apparent to one of skill upon reading the present description.

Each of the microstructures 102 includes a second photovoltaic layer 108 over the first photovoltaic layer 104 thereby forming a photovoltaically active junction. In various embodiments, the second photovoltaic layer may comprise a photovoltaic material that is complementary to the material of the first photovoltaic layer, and may include any of the materials disclosed above for the first photovoltaic layer. Moreover, the material of the second photovoltaic layer may be a similar material as the first photovoltaic layer but doped to be complementary thereto.

An outer conductive layer 110 is positioned over the second photovoltaic layer 108. In one approach, an outer conductive layer can be any suitable conductive film, however is preferably one that is transparent or semitransparent. Moreover, illustrative materials according to various approaches may include a transparent conductive oxide (TCO), which may include metal oxides such as zinc oxide with dopant, indium tin oxide, etc.; Cd₂SnO₄; etc. Furthermore, in one embodiment, the outer conductive layer may be applied full film to improve the durability of the array, as a thinner conformal layer, etc.

In one approach, the outer conductive layer 110 may be part of the microstructure. In some embodiments, a gap may be present between the microstructures, while in others, the outer conductive layer 110 may extend between the microstructures thereby electrically coupling them together.

According to one approach, the spaces between the microstructures may be: backfilled with another solid material; partially backfilled; completely void; vacated; filled with a gaseous material such as air, nitrogen; etc.

In yet another approach, the outer conductive material 110 and optionally at least one other solid material of a photovoltaic device 100 may fill a gap present between the microstructures 102 while having an index of refraction lower than the index of refraction of the second photovoltaic layer 108. Various embodiments may include but are not limited to encapsulant materials such as EVA, PVB, etc.

In continued reference to FIG. 1, one embodiment may include a substrate 112 of any suitable type. According to another embodiment, layers of such a substrate may be constructed by ion plating, pulsed laser deposition, sputter deposition, vacuum deposition, etc. or any method which may be known by one of skill in the art in correspondence with any of the possible substrates.

According to one approach, a flexible micropore substrate can be used as the substrate 112 for deposition of metal; and so the substrate may be made into any desired shape. While other PV tapes and films have 2D flexibility and strength in the XY directions, they are limited and no other technology allows for 3D, XYZ directional design of a rigid or flexible long lasting solar cell. The varied geometry of the solar brush allows the PV cells to be optimized for solar exposure from a fixed location, optimal aesthetic appeal, and minimal aerodynamic drag for transportation applications. Specific geometries combined with reflective substrates can effectively produce a combined PV film and solar concentrator.

In one embodiment, each of the microstructures may include a reflective core, which may be any core disclosed herein or as would be apparent to one skilled in the art upon reading the present disclosure. Each of the microstructures may further include a first photovoltaic layer over the core, and a second photovoltaic layer over the first photovoltaic layer thereby forming a photovoltaically active junction therewith. An outer conductive layer may additionally be positioned over the second photovoltaic layer, wherein an index of refraction of the outer conductive layer may be less than an index of refraction of the second photovoltaic layer, and the index of refraction of the second photovoltaic layer may be less than an index of refraction of the first photovoltaic layer.

In addition, or alternatively, a bandgap (Eg1) of the outer conductive layer may be larger than a bandgap (Eg2) of the second photovoltaic layer, and the bandgap of the second photovoltaic layer is larger than a bandgap (Eg3) of the first photovoltaic layer,

Eg1>Eg2>Eg3

In another approach, a photovoltaic device may include an array of microstructures which is arranged in a brush configuration. FIG. 2 is a perspective view of an exemplary solar brush 200 that may be used to implement solar cells with improved efficiency, the solar brush 200 having a substrate 112 and an array of microstructures 102, also referred to herein as bristles.

In one approach, the bristles may be modified incorporating materials that may serve as improved back contacts. Various embodiments may include such materials as Sn, An, Cu, C, Sb, Au, Te polymers, metal oxides, Si, SiO₂, S, NiO, Ni₂O₅, NiS₂, Zn, Sb₂Te₃, Ni, NiTe₂, Si, SiO₂, Cu, Ag, Au, Mo, Al, Te/C, etc. or any other improved back contact layer that may be apparent in various embodiments to one of skill in the art upon reading the present description including combinations thereof.

It should also be noted that though the axes of the bristles are oriented normal (perpendicular) to the plane of the array in the drawings, the axes of the bristles may be tilted slightly (a few degrees from normal) or pronouncedly (e.g., 40-89 degrees).

According to some embodiments, bristles protruding at angles may increase the amount of semiconductor materials exposed to the sun when the sun is directly overhead and may improve internal reflections.

A surprising change in power output of an array of bristles has been observed according to one embodiment based on theta rotation, or rotation of the array in the plane of the substrate for a given light source location. Particularly, the power output of the array increases and decreases as the array is rotated, including an observable peak power output as the array is rotated. While not wishing to be bound by any theory, it is believed that the unique brush configuration of microstructures and the properties thereof create this phenomenon. Accordingly, one using a particular embodiment may select a combination of theta rotation and initial presentation angle relative to a light source position to maximize power output.

Bristle angles can be created, for example, by heating a polymer membrane and creating an asymmetric drag to get a template with tilted apertures into which a material may be formed, e.g., by electroplating. Deformation of the template may be done by having a heat source, a source of drag, and an optional cooling source. One example would be a doctor blade scraping the heated top of a polymer membrane. A heated air knife could be used to replace the doctor blade in another approach. This also could be done with two contact rolls where one roll is cooled and moving at slow speed and roll is heated and moving at a slightly faster speed. Additionally, seeding processes or vapor processes can be used on tilted surfaces to grow microstructure arrays at angles. Various shapes can be obtained using asymmetric pore membranes.

Pseudo tilting can also be accomplished by controlling the profile shape of the bristles so they are shaped with top diameters or widths being smaller than the bottom diameters or widths, e.g., with a conical or frusto-conical profile, pyramidal or frusto-pyramidal profile, etc., thereby exposing the bottoms to the collimated light of the sun or other light source. Thus, though axes of the bristles may be oriented perpendicular to the substrate, the wider bottom enhances the exposure of the bristles to collimated light.

The brush configuration also has flexible manufacturing options including membrane manufacturing technologies or photolithography e-beam, low density layered mechanical scoring, microporous templated, electroplating, and electrical arcing. These manufacturing methods can be used on a variety of membrane/microporous media which allows cell to be shaped and hardened to geometry that has maximum solar efficiency, maximum aerodynamic efficiency, maximum aesthetic appeal or a combination of the aforementioned attributes. Flexible units can also be achieved by daisy chain connection between small rigid units or from the use of a flexible substrate.

In another embodiment, segmented areas could be bussed prior to plating such that energy could be delivered to one part of the array and not others. By switching segments on and off, two or more different materials could be plated on different portions of the array. The segmentation could bus not only individual rows of a solar brush, but with patterning techniques to those skilled in the art one bus every other microstructures in a basket weave type design, or any other possible division of microstructures.

When designing a PV cell, one of the considerations is the photon flux. The number of photons that make it through the atmosphere at a given point remains relatively constant regardless of modifications in the PV cell that receives them. When determining the appropriate geometry for a PV cell, it is convenient to start by calculating the area of the gaps and the area of the bristle-tops.

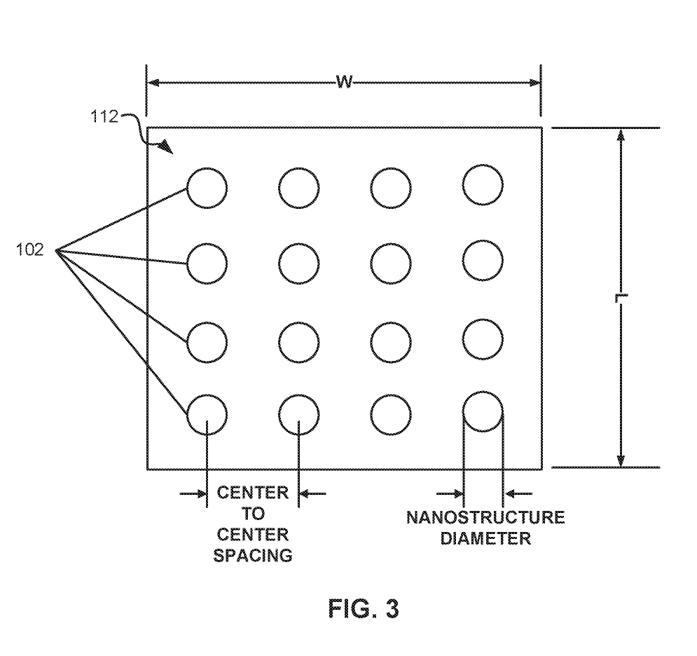

FIG. 3 is a top view of the solar brush 200 showing the tops of the microstructures 102. Although the microstructures 102 are shown to be arranged regularly, this arrangement can be changed to suit the application. Moreover, the number of microstructures depicted in FIG. 3 is in no way meant to limit the size of the solar brush 200.

According to one approach, the area between solar bristles could be sufficiently wide as to make the brush absorptive to the majority of photons. For example, an illustrative average center to center spacing of the microstructures in the array is between about 1 and about 30 microns, but could be higher or lower. Additionally, the bristles may be thin enough to be partially transparent. The combination of effective transparency and bristle spacing may increase effective energy generation to extend from sunrise to sunset while flat PV cells work optimally when the sun is straight above the PV surface. If the materials are sufficiently thin, electron-hole recombination minimizes damage cell efficiency, and up to a 15% gain above that of 29% theoretical efficiency of a single junction cell becomes possible. This would allow use in small applications such as charging electronic devices (cell phone, computer, PDA, etc.), use in medium scale applications such as light weight roof-top energy for industrial and agricultural power generation, and use in large applications such as a light weight energy source for transportation (automobile, aircraft, barges, etc.). The efficiency of the cell would also enable improved power generation in low light conditions; and possibly even power generation from infra-red light during night time.

In another embodiment, one or more electrically conductive strips may extend across an array of photovoltaic devices, or portion thereof to assist in carrying electricity away from the array, thereby improving the overall efficiency of the brush. The efficiency gains are more pronounced in larger arrays. Such strips are preferably very thin to block minimal light.

High temperature degradation is mitigated because each component of this PV cell can be sized to minimize thermal expansion and can be further optimized with flexible expansion joint conductive connections between PV arrays. Additionally, the greater surface area of the solar brush will reduce thermal heat generated under the PV solar cell more efficiently compared to the conventional planar unit. One further advantage is that micro conductors often have reduced resistance at higher temperatures; therefore, the PV brush could be able to transfer energy more effectively than conventional PV cells at higher operating temperatures.

In one approach, each of the microstructures is characterized as absorbing at least 70%, more preferably at least 90%, more preferably 95%, ideally at least 99%, of light passing an inner surface of an outer layer thereof towards an inside of the microstructure. The outer layer may be the outer conductive layer, an overcoat, an encapsulant, etc. The high rate of light absorption assists in creating much more electron hole pairs than approaches where the light can escape. The high capture rate, thus, is believed to lead to an increased current density, which is due in part by a more sophisticated rate at which energy of the light photons is captured.

In one embodiment, and with continued reference to FIG. 1, the high absorption rate is enabled at least in part because an index of refraction of the outer conductive layer 110 is less than an index of refraction of the second photovoltaic layer 108. The index of refraction of the second photovoltaic layer 108 is less than an index of refraction of the first photovoltaic layer 104. “Index of refraction” in the context of the present description is understood to refer to the measure of the speed of a wave through a particular medium, which in turn refers to the measure of the speed of light through the conductive layer, second photovoltaic layer, first photovoltaic layer, etc. Index of refraction for a given material can be determined using the equation:

n=Vᵥ/Vₘ

where n represents the index of refraction, Vᵥ represents the well-known speed of light in a vacuum, and Vₘ represents the speed of light in the given material.

According to some approaches described herein, the photovoltaic device so constructed may act as a solar/light concentrator.

Power generation and effective areas for a microstructure can be significantly boosted when the microstructures each act as a solar concentrator. For example, a solar concentrating microstructure may redirect large areas of light perpendicular to the surface, thereby utilizing the PV materials at the depths of the bristle. The effective area of the solar cell is calculated by dividing the penetration depth by the bristle height and multiplying it by the area. The power output of a high efficiency, high area solar cell in one embodiment is between 50 and 285 kW/day/m² with a solar concentrator. The output ranges compare favorably with the maximum output of 0.94 kW/day/m² based on the best known field results ever for planar single silicon PV arrays that are produced with a process which is probably much more costly than the methods and structures presented herein.

In one approach, each of the microstructures may be physically characterized as concentrating photons near the core thereof, e.g., in the PV layer closest to the core and any layers lying therebetween. The concentration of photons may be equivalent to greater than 1 and about 100 times a photon impingement on a bare core when exposed to a same light source, but may be higher or lower based on the embodiment. According to the present approach, a bare core may mean there are no overlying layers. Moreover, the concentration of photons may be characterized by photoluminescence of light in the near infrared to infrared wavelength ranges. In some approaches, each of the microstructures may be physically characterized as concentrating photons near the core thereof, the concentration of photons being equivalent to greater than 1 and about 100 times a photon impingement on a planar photovoltaic device per unit two dimensional area of a profile of the respective device, when exposed to a same light source. Thus, even though the core is only a fraction of the profile area of the microstructure, the concentration effect concentrates photons there, to an extent even greater than occurs in a planar photovoltaic device.

Without wishing to be bound by any theory, it is believed that the variation in the refractive indices between the layers of the microstructure allow for light bending, which causes the photons to concentrate near the core. It is also believed that as the bandgap value of the photovoltaic layers decreases towards the core, the photons create an excitation process where electron hole pairs are being formed. These electron hole pairs are formed when a photon enters a layer and has as much, or more energy than the bandgap, thus causing an electron to jump from the valance band to the conduction band. So it is believed that the varying refractive indices in combination with the decreasing bandgaps toward the core of the microstructure help promote photon concentration.

In another approach, each of the microstructures may be physically characterized as concentrating or funneling excitons from the outer photovoltaic layer to the inner photovoltaic layer to the core thereof. In one approach, this may be caused by the decreasing bandgap values towards the core of the microstructure, resulting in the exciton energy transfer process, as is well known in the art. Again, without wishing to be bound by any theory, it is believed that the photon concentration at the core of the microstructure is a result of the concentration of excitons at the core as well.

Therefore, it is believed that photon concentration at the core of the microstructure causes photoluminescence (PL), through the radiative relaxation of excitons. Therefore a single photon is able to produce multiple excitons before losing enough of its energy to be fully absorbed. Effectively, PL allows for one photon to produce the same amount of excitons as multiple photons in previous designs.

As a result, it is believed that this PL results in a higher current as well as a higher photon quantum yield than other photovoltaic designs. Conducted experiments are believed to have proven this theory by achieving currents up to 50 times higher than any planar photovoltaic device.

In another approach, a single photon having energy of about two to three times the bandgap or of the photovoltaic absorber layer can cause the electron to excite from the valance band to a higher energy state in the conduction band. The electrons in higher energy states, as they relax to low and stable energy states in the conduction band, gives their energy to other electrons in the valance band to excite them to the conduction band. This further gives rise to multiple excitons, and hence enhanced photo carrier generation and increased current density.

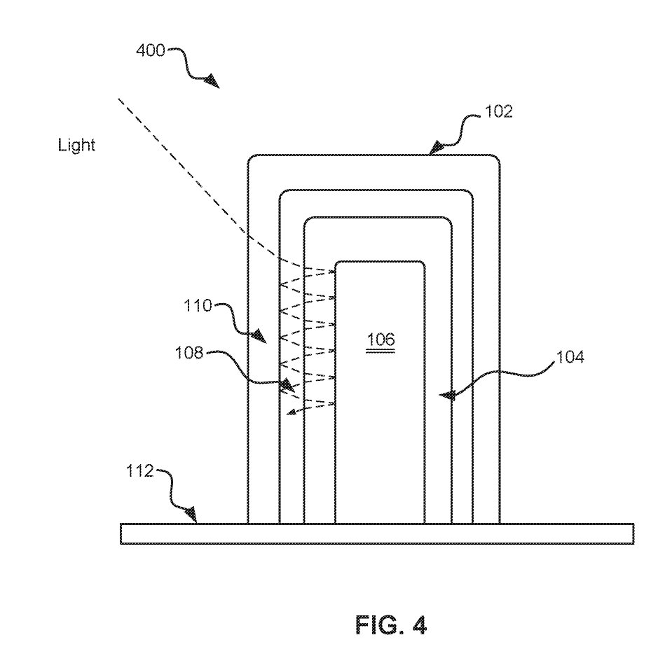

Each spectrum of light has a unique wavelength corresponding to it. Therefore, an absorption region of the same width, or wider than a particular photon's wavelength is generally required in order to transfer all of the photon's stored energy. Conventionally, thicker absorbing layers have been desired in that they are able to absorb energy from light with longer wavelengths. However, without wishing to be bound to any theory, it is believed that the three dimensional embodiment as shown in FIG. 4 allows for full absorption of light with wavelengths much longer than the thin absorption region.

In one approach, the photovoltaic device may be designed so that an effective optical path length of each of the microstructures may be at least 40 microns for light in a spectrum from visible to infrared to be absorbed. The effective optical path length may be obtained by varying the height and circumference of the microstructures, as to improve the chance of conversion for the different light spectrums as the photons are able to travel longer distances. At least 90%-99% (or more) of the light in the spectrum that passes through the outer conductive layer of the present approach may be absorbed.

The reflection and/or refraction that occurs at interfaces of the various layers results in “apparent” film thicknesses based on the reflection and/or refraction of the photon once inside the bristle. The reflection and/or refraction can be tuned by selecting materials with a particular reflective and/or refractive index. Thus, every time there is a reflection at a different angle or a different presentation, the apparent thickness of the film to the light is different. Each time the apparent thickness is different, there is a tuning effect based on the wavelength of the light. Accordingly, the quantum confinement and the energy conversion are slightly different for photons entering at different angles, with respect to film thickness. It is believed that according to one embodiment, if the PV films are thin, and the incoming light includes a high frequency, high energy wavelength like violet, the light gets confined primarily to the thin PV layers resulting in a quantum effect. In areas or embodiments with thicker films, the tuning factor may be more effective for red light. Thus, a combination of presentation angles, material selection, film thickness, and small grain size work as a system to capture the broader spectrum of light, and use it as efficiently as possible. Without the bristle structure one would expect not to observe these effects.

One embodiment is depicted in FIG. 4, in which the outer conductive layer 110 may have a roughness from being aluminum doped, making it conductive. This may also create a scattering effect, thus preventing a photon from escaping the photovoltaic device 102 before the photon's energy can be fully absorbed. In addition, the outer layer of a core 106 reflects the photon back away from the core 106.

With continued reference to FIG. 4, the photon is effectively trapped between the outer conductive layer 110 and the core 106 (or other layer between the PV layers and the core), thus continually reflecting within the inner and outer photovoltaic layers 104, 108 with a unique path, until all the energy of the photon has been depleted.

As depicted in FIG. 4, the microrod surprisingly generates a waveguide effect that traps light coming into the microrods. This is in sharp contrast to conventional wisdom which expected that photons would bounce between the rods rather than being contained within them. Furthermore, the surprising tendency of light to be trapped in the microrod by the waveguide effect greatly increases it's absorption efficiency.

In another embodiment, the microstructures may be physically configured to create standing waves of photons therein when impinged by light. Without wishing to be bound by any theory, it is believed that a continual incidence of solar radiation onto the outer surface causes wave resonance and/or acts as a pumping system. An illustrative example of such a pumping system allows for standing waves or a superposition of standing waves of photons to develop allowing the length of the absorption layer, developing a steady state solution. This allows the entirety of the absorber material to be utilized. In other words, if a continual light source were positioned so that only half of the photovoltaic microrod was exposed to a light source while the other half was shadowed, once the photons entered the inner surface of an outer layer, a standing wave develops, thus activating the entirety of the absorption layer, not only the half that was directly exposed to the continuous light source. Therefore device efficiency as well as device current density are increased even in cases where light sources are positioned unfavorably.

In another approach, the microstructures may be configured to act as microantennas. It is believed that certain microstructure designs allow the microstructure to act as a resonant cavity where the light electromagnetic waves oscillate. This is believed to provide a quantum mechanical waveguide coupling that enhances the photon capture cross-section. This enables the collapsing and capturing of more photons. In some approaches, the quantum mechanical waveguide coupling to enhance the photon capture cross section from may increase the effective capturing cross-section of the microstructure by greater than 1 time therealong, at least about 2 times, from about 2 to about 1000 times, etc. relative to the perpendicular (deposition) thickness of the absorber layer.

Consequently, as photons are captured by the microstructure, it is believed that the outer layer of the microstructure builds up positive charges, while the core of the microstructure builds up negative charges. After this charge has been established, the microstructure is believed to interact more efficiently with incoming and available light photons in the atmosphere. It is believed that this structure increases the probability that the wave nature of the photon will collapse at the outer edge of the microstructure, and the photons are essentially pulled inside the outer layer into the microstructure. It is believed that this microantenna effect should be effective on light in the ultraviolet range, visible range, and infrared range according to different embodiments.

As described above, after the photons enter the microstructures, they are effectively captured and create standing waves or a resonance within the structure. Without wishing to be bound by any theory, it is believed that this resonance is caused by the electrons and the holes lining up and vibrating.

According to one embodiment, the microstructure side walls effectively act as a combination of cylindrical lenses when there is an increase in the index of refraction on the various thin films as one travels inward from the outer layer. In one approach, the inner surface of the outer conductive layer may be concave about a longitudinal axis of the microstructure closest thereto. The inner surface of the outer conductive layer may also reflect light already inside the microstructure back into the layers underlying the outer conductive layer.

In sharp contrast to the effect of light entering a planar surface, and without wishing to be bound by any particular theory, it is presently believed that the light that passes the inner surface of the outer layer of the microstructures disclosed according to various embodiments undergoes a spiraling effect. Again, without wishing to be bound by any theory, it is believed that the light is transmitted to the higher indices of refraction, and is not able to escape, partially due to the discrepancy in the index levels at the different layers. Moreover, once past the inner surface of an outer layer (inside the microstructure), the light encounters a concave inner surface of the outer layer and in most instances is prevented from escaping. Therefore, once the light is in the layers below the inner surface of an outer layer, the light sees an inward curvature, and so is more prone to total internal reflection; whereupon, it is also more probable for the light to be transferred into a material having an even higher index of refraction, and hence into the absorption layer. As a result, and without wishing to be bound by any theory, it is believed that this increases generation of the electron-hole pair by effectively increasing the distance that the photon travels though the microstructure. Ultimately the innermost layer of the microstructure may be an interface that acts substantially as a mirror, thus keeping the light between the core and the outer layer of the microstructure.

Note that light which strikes the outer layer, e.g., TCO, about tangentially may pass through the TCO and to the next microstructure in the array, where it will get absorbed. For example, it is possible for light to skim the outer layer about tangentially, without actually passing through the inner surface of the outer layer.

The theoretical efficiency of a single junction (2D) solar cell is generally accepted to be around 31% for a CdTe solar cell. However, in another approach, the array of photovoltaic devices is characterized as providing a total effective Quantum Photovoltaic Device Efficiency having an equivalent planar solar cell efficiency above the theoretical efficiency limit of any planar solar cell of any type currently on the market as of the filing date of this application, on a non-normalized area basis. A non-normalized area basis refers to a 2D dimension in the plane of the solar cell and array. Particularly, the plane of the array is generally defined as a plane extending crosswise through the axes of the photovoltaic microstructures, typically parallel to the substrate. The flat panel photovoltaic device used as the benchmark can be any known flat panel photovoltaic device.

The definition of Quantum Photovoltaic Device Efficiency (QDCE) is related to equivalent planar Photovoltaic Device Efficiency by the following formula:

QDCE=[Voc×Isc×FF]/[Quantum Device Area×Solar Concentration×100 W/cm²] a.

where Voc=open circuit voltage;

Isc=short circuit current;

FF=fill factor that determines the maximum operating power point of a solar cell, defined as the ratio=(Vmax×Imax)/(Voc×Isc);

the Quantum Device Area is the physical active area of the photovoltaic device available per square centimeter for capturing the sunlight, calculated as the area of each cylindrical bristle multiplied by the total number of bristles available per active cell area in square centimeters and multiplied by a factor (from 0 to 1) representing an area of the array exposed to sunlight; and

the solar concentration is the optical concentration of photons produced by the quantum cell optics at the core.

The Equivalent Planar Photovoltaic Device Efficiency (EPDE) is represented by the following formula:

EPDE=[Voc×Isc×FF]/[Planar Device Area×100 W/cm²]

In preferred embodiments, the array is at least about 2× and preferably at least about 3×, and ideally 3× to 5× the theoretical efficiency limit. In one approach, the value is about 4×. Without wishing to be bound by any theory, it is believed that the improved efficiency limit, as well as the high current density, are caused by the cylindrical outer periphery of the photovoltaically active microstructures.

In one embodiment, the array of photovoltaic devices may be characterized as providing greater than 100% efficiency per unit 2D area oriented parallel to a plane of the array, compared to equivalent planar photovoltaic device efficiency.

The added dimension of the photovoltaically active microstructures allows for extra surface coverage when compared to the conventional planar structure. Although, in one embodiment the current density remains constant for a given 2D area, more current may be extracted due to the utilization of the extra dimension.

In another embodiment, higher current density is achieved for a given 2D area due to the improved efficiency of the photovoltaic device to about 95% while converting. In yet another embodiment, both the improved efficiency, as well as the added dimension may be combined to result in a photovoltaic device with an improved current density.

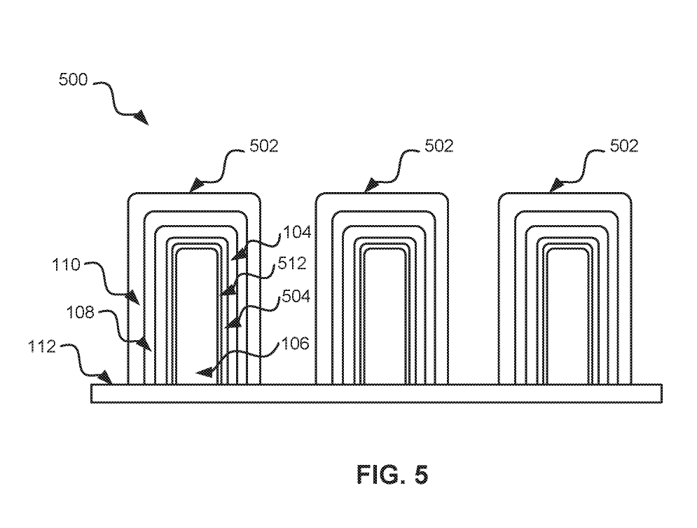

In one approach, the photovoltaic device 102 may include a dielectric layer 504, as shown in FIG. 5, between the core 106 and the inner photovoltaic layer 104. Such a dielectric layer may act as an improved photon reflection layer while also shielding any of the photon's energy from being lost to the core 106 thereby contributing to an increased current density. In one approach, the dielectric layer may be a layer of TCO which may include Fluorine doped SnO₂—F, aluminum doped AZO, indium doped ITO, etc.

In some approaches where the dielectric layer 504 is a TCO layer, the TCO may be applied in a heated liquid form. Accordingly, in one embodiment, the liquid may be hot enough so that the TCO deposition and any heat activation of the cell may be combined in one step; thereby the heat from the TCO may effectively activate the PV cells.

In one embodiment, heat activation can be performed with lasers. One advantage to this is that very little energy is wasted and the carbon footprint is minimized. Often modules are activated in ovens where most of the energy is lost to the environment. Another advantage is that the correct amount of energy is applied to the PV cell. When cells get too much or too little energy, the cell performance is reduced. Finally, the lasers can be pulsed such that some microcables receive more energy than others. This can be particularly helpful when multiple materials with differing activation requirements are found in the PV array.

FIG. 5 depicts an illustrative example of a photovoltaic device 500 where each of the microstructures 502 has an intervening layer 512 positioned between the core 506 and the dielectric layer 504 thereof.

In one embodiment, an intervening layer 512 may be Al, Mo, Au, Ti, TiW, etc. or any other barrier layer that may be apparent in various embodiments to one of skill in the art upon reading the present description.

In another approach, an intervening layer may have a deposition thickness of between 0 and about 2500 angstroms. In a preferred embodiment, the total intervening and dielectric layer thicknesses may vary from 0 to 5000 angstrom, with most optimized value range from 1000-3000 angstrom. “Between 0” in the scope of the present approach is not inclusive of 0, but rather denotes a lower value that is greater than 0.

In one detailed example, a photovoltaic device where each of the microstructures may have a dielectric layer positioned between the core and the first photovoltaic layer thereof, where the dielectric layer may have an extinction coefficient k of about 0. In a preferred embodiment, k may be in a range greater than 0 to about 0.05, more preferably greater than 0 to about 0.02.

In yet another approach, the microstructures may have an intervening layer positioned between the core and the first photovoltaic layer thereof. In one approach, the intervening layer may have a deposition thickness of between 0 and about 2500 angstroms. In another approach, such intervening layer may be electrically conductive.

In yet another approach, the intervening layer may promote adhesion of overlying layers to the core. In various approaches an intervening layer may include any of the intervening layer materials disclosed herein or any other intervening layer which would be obvious to one of general skill in the art upon reading the present description. According to one illustrative example, an intervening layer including molybdenum may work exceptionally well with a core which may include nickel.

In one embodiment, the intervening layer may have a sheet resistance of about 0 to about 50 ohm/sq. In a preferred embodiment, the range of the sheet resistance of the intervening layer may be about 0 to about 30 ohm/sq.

With continued reference to FIG. 5, in another possible approach, a dielectric layer 504 may be a substantially transparent electrically conductive dielectric layer. In another approach, a photovoltaic device 500 where each of the microstructures 502 may have an electrically conductive dielectric layer 504 positioned between the core 506 and the first photovoltaic layer 104.

In various approaches, a dielectric layer may include a substantially transparent electrically conductive dielectric. Various approaches may incorporate a substantially transparent electrically conductive dielectric layer which may include, but is not limited to various types of TCO such as SnO2:F, ZnO, AZO, ITO, NiO, etc. or any other substantially transparent electrically conductive dielectric layer which would be apparent in various embodiments to one of skill in the art upon reading the present description. In further approaches, the electrically conductive oxide layer may have a deposition thickness of between 0 and about 2500 angstroms, and may act as or as part of an intervening layer. “Between 0” in the presence of the present approach is not meant to include 0, but rather denotes a lower value that is greater than 0.

In one approach the dielectric layer may be, but is not limited to being a transparent conducting oxide.

Generally, one would expect an oxide layer to detrimentally affect performance by creating too much electrical resistance for proper operation of the array. Surprisingly, and counter to conventional wisdom, such an oxide layer was formed in an experiment, and was found to not cause an overly-detrimental effect on electric performance of the array. According to one illustrative experiment, a thin layer of NiₓO_{y} formed on the Ni lower contact due to exposure to oxygen. Moreover, a CdTe layer was formed thereover. The array functioned surprisingly well. Accordingly, in some embodiments, a layer of metal oxide may be formed between the lower contact and the PV materials. Such layer of metal oxide in various approaches may be formed, e.g., by exposing the lower contact to an oxygen-containing environment (e.g., air, ozone rich atmosphere, etc.) preferably while being heated (e.g., to >100° C.); barrel ashing; etc.

Without wishing to be bound by any theory, it is believed that there is a skin depth loss associated with nickel being used as the back contact material. It is believed that a photon's field penetrates the nickel slightly, and as a result an evanescent wave develops in the nickel which decreases the total intensity of the photon. However, these losses may be prevented by putting a thin dielectric material over the nickel, without decreasing the current transmission capability of the material toward the back contact. It would be preferred if the complex index of refraction, or extinction coefficient of the dielectric layer, was minimal, so to enact the concentration effect in an attempt to achieve total internal reflection.

In another embodiment, it may be desired to design the dielectric layer as to prevent any losses at the interface, while also ensuring that the dielectric material is thin enough to allow for generated electrons and holes generated in the depletion region, to travel through the dielectric layer, which may include quantum tunneling, interfacial surface states, etc. or combination thereof.

Referring again to the photovoltaic layers of various embodiments, a depletion region may be formed when two opposite junctions are brought together, such as the p-type and n-type of a material. Electrons and holes diffuse into regions with lower concentrations of electrons and holes, conceptually, much as ink diffuses into water until it is uniformly distributed. By definition, an n-type semiconductor has an excess of free electrons compared to the p-type region, and a p-type has an excess of holes compared to the n-type region. Therefore when n-doped and p-doped pieces of semiconductor are placed together to form a junction, electrons migrate into the p-side and holes migrate into the n-side. Departure of an electron from the n-side to the p-side leaves a positive donor ion behind on the n-side, and likewise the hole leaves a negative acceptor ion on the p-side. Following transfer, the injected electrons come into contact with holes on the p-side and are eliminated by recombination. Likewise for the injected holes on the n-side. The net result is the injected electrons and holes are gone, leaving behind the charged ions adjacent to the interface in a region with no mobile carriers, called the depletion region. The uncompensated ions are positive on the n side and negative on the p side. This creates an electric field that provides a force opposing the continued exchange of charge carriers. When the electric field is sufficient to arrest further transfer of holes and electrons, the depletion region has reached its equilibrium dimensions. Integrating the electric field across the depletion region determines the built-in voltage (also known as the junction voltage or barrier voltage or contact potential). Therefore, the distance between p-type and n-type junction is called a depletion region.

Without wishing to be bound by any theory, the planar structure's thicker absorber layer is believed to cause the charge carriers to be lost due to the wider depletion region which creates a higher likelihood for a fundamental recombination to take place, thus losing electrons as charge carriers. However, the exemplary thinness of the absorber layer in comparison to that of the planar structure minimizes the distance that the electrons, as well as the slower moving holes, are required to travel to reach the electrodes. Additionally, a strong electric field may be applied to give the charges an increased acceleration. The combination of a thinner depletion region, as well as a strong electric field is believed to result in obtaining a much lower Shockley-Read-Hall (SRH) recombination rate, which correlates to a higher achieved current density.

In one approach, an absorber layer's dimensions are capable of being very thin; in one embodiment, between about 0.1 and 0.5 microns thick; therefore minimizing the depletion region between the p and n junction compared to the conventionally much thicker absorber layer used in planar structures.

In another approach, the microstructures may each have only a single photovoltaically active junction, where a total material thickness between the core and the outer periphery is between 0.01 micron and about 10 microns. Note that the outer periphery may be defined by an outer surface of an overlying conductive layer, and/or an inner surface (core-facing surface) of an outer conductive layer. In a preferred embodiment, the total material thicknesses between 0.01 and 6 microns.

In one embodiment, the microrods may be comprised of multi-junctions, whereupon multi junctions may involve adding another layer of materials and/or p-n junction. Multi junctions are beneficial in that they incorporate materials with multiple band gaps to gain larger spectra which will function over a wider range of photon wavelengths. Under certain embodiments, it may be desirable to increase the diameter of the microrods to compensate for the additional layers of material being added to the microrods.

In another approach, a microstructure may each have at least one additional layer creating at least a second photovoltaically active junction such as that corresponding to third 944 and fourth 946 photovoltaic layers, as shown in FIG. 9. In one approach, the photovoltaically active junctions may have different or the same bandgap values. In general embodiments, the at least one additional layer that creates the at least a second photovoltaically active junction may be another cell. In an illustrative example, a CdTe and CdS layer may be used as a first cell, then another absorber layer (e.g., CdTe with different doping, a different material, etc.) may be added thereabove. More than two junctions are contemplated, e.g., 3, 4, 5, etc. Moreover some of the bangaps of the absorber layers may be the same, some may be different, some may be graded, and any combination thereof. One option uses the same base materials, which may in one embodiment, utilize CdTe layers sandwiching a CdS layer. Another way to change the bandgap of the material to vary from a higher bandgap to a lower bandgap is to grade a cell into a triple junction, a double junction cell, etc.

There are a few embodiments of basic multi-junctions; the first being same type, where, in one approach, there may be CdTe on CdTe in order to increase the range of wavelengths captured. Secondly, under a different approach, a graded band gap may be formed by grading a CdTe to cover a range of band gaps, again in order to increase the range of wavelengths captures.

In another approach, a photovoltaic device may incorporate microstructures which may each have layers creating at least one photovoltaically active junction. According to one embodiment, the at least one photovoltaically active junction may have a bandgap value that varies in a thickness of deposition direction of the photovoltaic layers. Such embodiment may be formed by grading the materials forming the photovoltaically active junctions. Bandgap grading may be conducted in a number of ways. One option uses the same base materials, such as laminating CdTe layers of differing composition. Another approach applies bandgap altering dopants at different concentrations at differing deposition thicknesses. Thus, the bandgap value can increase or decrease in the thickness direction, can have a stepped gradient, etc. Moreover, the degree of increase or decrease in bandgap can vary nonlinearly across the thickness, or may be linear.

In another embodiment, a multi junction source may have a varying band gap while also possibly allowing for light reflected by a first cell to travel to the next cell

In another approach, a photovoltaic device may have a depletion region that extends across an entire thickness of an absorber layer of the photovoltaic layers. In one approach, the absorber layer of a CdTe/CdS system may include CdTe.

In another approach, a photovoltaic device where the microstructures may each have layers creating at least one photovoltaically active junction, where a depletion region of one, at least two or all of the layers may extend across the entire thickness of the one, at least two or all of the layers.

In another approach, a photovoltaic device where depletion regions of the first and second photovoltaic layers may extend across the entire thicknesses of the photovoltaic layers.

In still another approach, a photovoltaic device where one, at least two or all of the microstructures may include an n-type first photovoltaic layer, a p-type second photovoltaic layer over the first photovoltaic layer, and an n-type third photovoltaic layer over the second photovoltaic layer. The n-type and p-type materials can be of any known semiconductor photovoltaic material know in the art such as CdTe/CdS, a-Si, GaAs, CIGS, poly-crystalline Si, organic, polymeric, etc. This device may also be deposited in p/n/p formation, where the junction in between the second and third layers may be a tunneling junction by heavily doping the ending n or p layer, e.g., n++, p++, etc.

Another potential benefit may be achieved by layering material with different band gap values. According to one embodiment, it is desirable to have a high band gap material such as GaAs (max efficiency ˜20%, band gap ˜1.4 eV) or CdTe (max efficiency ˜30%; band gap ˜1.6 eV) at the tip of the bristle and a reduced band gap material further down the bristle such as CIS or CIGS type PV material further down (max efficiency of ˜24%; band gap ˜0.8 eV). Photons with low energy will not react with high band gap material but will be available to react with low band gap material further down the bristle at further penetration depths. This could be achieved by CVD of CIS material on a microcable, followed by etching to the top metal core of the microcable, followed by catalytic growth on top of the microcable, and the cable may be completed by electroplating of CdTe/CdS. The solar brush PV cell design could also be a multijunction cell and is a superior architecture for such. Multijunction cells could be easily accomplished by depositing layers of different materials stacked on top of each other. These deposition methods can be diverse and include any method currently used in the art.

In one approach, the photovoltaic device may include a transparent conductive oxide or optically thin metallic material between the first photovoltaic layer and the second photovoltaic layer. In another approach, a transparent conductive oxide or optically thin metallic material may be included between the second photovoltaic layer and the third photovoltaic layer. In various approaches, the TCO may include any type which is known in the art. Illustrative thicknesses of such layers may be greater than 0 to about 100 micrometers, and in a preferred approach, up to about 20 angstroms. Illustrative materials are TiO₂; ZnO; Cs₂CO₃; TiO₂:Cs₂CO₃; MoO₃; ultra-thin (<5 nm) metal layers such as Au or Ag; etc.

Surprisingly and contrary to conventional wisdom, it has been found that some embodiments using thin films exhibit greatly improved performance. While the precise mechanisms are not completely understood, and without wishing to be bound by any particular theory, based on laboratory observations and modeling, it is believed that such embodiments take advantage of quantum confinement. Particularly, the architecture of some embodiments allows quantum confinement to be a controlled process. While the exact nature of quantum confinement is not completely understood, and without wishing to be bound by any particular theory, the behavior of the photovoltaic mechanisms is enhanced when quantum confinement occurs. For example, more than one electron per photon may be obtained. Moreover, more powerful electrons may be obtained.

In addition, it has been surprisingly and unexpectedly found that more powerful electrons may be obtained due at least in part to what is referred to herein as the “blue shift” phenomenon. Particularly, as will soon become apparent, the tuning film thickness may allow a PV cell to take advantage of higher energy shorter wavelength photons in the blue, violet and near UV range to increase output. In traditional systems, one photon goes into a PV cell and one electron comes out. The electron is of a certain power, called the band gap of that power. Again, without wishing to be bound by any particular theory, it is believed that particular features of the microstructures described herein allow shorter wavelength, higher energy light in the blue, violet, and near UV wavelengths to reach higher energy electrons surrounding the nucleus of the PV material. The tunability of various embodiments with regards to light wavelength and the blue shift phenomenon is believed to allow power output of about 2.1 electron volts while the standard “red area” is believed to allow only about 1.45 electron volts. In other words, with traditional bulk material, there is one band gap, i.e., one valence electron that is available so no matter what light color comes in, any excess energy is converted to heat. Accordingly, if a red photon comes in that was almost completely matched to that band gap, most of its energy would be used. If a shorter wavelength, higher energy photon came in that has substantially more energy, it would still cause release of an electron, but there would be an energy loss; in other words any excess energy that the blue photon has would be converted to heat. Thinner films create a quantum confinement that make this energy available by allowing the higher energy photons to reach deeper into the valence shell and eject electrons closer to the nucleus that have a higher energy. The higher energy photons may also cause release of two electrons, each of lower energy the sum of which would be more closely matched to the input energy of the higher energy photon. Thus, some embodiments are characterized by a capability to produce more than one electron per photon engaging the array of photovoltaic microstructures, for one or more of the photons engaging the device when the device is placed in light. Particularly preferred embodiments include electrically conductive microcables with thin films of PV material thereon. The thin films of the constructions disclosed herein result in more conversion effects (events), and more quantum effects. The smaller average thinness of the films produces better quantum confinements, which allows access to discrete energy levels.

The thin films may be employed in any embodiment disclosed herein and the many permutations thereof, as well as in those described and inherent in U.S. Pat. No. 7,847,180, U.S. patent application Ser. No. 11/466,416, and U.S. Patent Appl. Pub. No. US-2010-0319759-A1, which are herein incorporated by reference. It is presently unknown whether the noted quantum effects would occur in planar embodiments, though such embodiments are not foreclosed. It is possible that planar films may not provide the noted quantum effects because the film may be so thin that when a photon comes in it might just bounce out and not be absorbed. Regardless, formation of the layers on a microcable provides several benefits such as stress relief, fewer defects, enhanced absorption and quantum effects due to multiple photon bounces, etc. Moreover, construction on a microcable reduces recombination versus a planar substrate as well because in a microcable, the junction is much closer to the conductive core. Lower recombination may be highly critical to the performance of the cell according to one embodiment, because it allows the device to sustain necessary voltage and current levels for high performance with lower incidences of the electrons recombining and the cell thus losing the energy to heat.

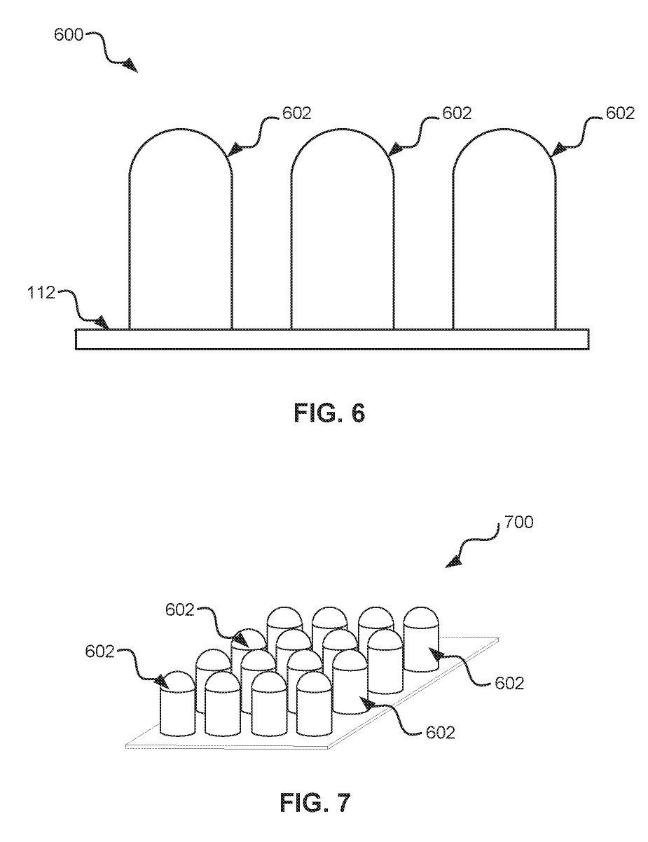

Further embodiments may incorporate a domed tip as is depicted in FIGS. 6-10B. The construction of such embodiments may be the same as for the microstructures described above in reference to FIGS. 1-5 or any other configuration as would be apparent to one skilled in the art upon reading the present disclosure, except for the incorporation of a domed tip, and possibly domed inner layer. Other constructions as disclosed herein may also be used. The domed tip further enhances the light capture effect due to concavity and further reasons which will be discussed below.

FIG. 6 depicts one general embodiment, in which a photovoltaic device may incorporate an array of photovoltaically active microstructures 600 which may have a substrate 112. According to another approach, the photovoltaic device may have each of the microstructures characterized as absorbing at least 99% of light passing through an inner surface of an outer layer thereof.

In another embodiment, each photovoltaically active microstructure 602 may have a generally cylindrical outer periphery and a dome-shaped tip. In one embodiment, each of the microstructures may have has a dome-shaped tip.

In one approach, each of the microstructures 602 may be characterized as absorbing at least 90% of light passing through an outer layer thereof. In another approach, the outer layer of the microstructure may incorporate a TCO layer, and at least 90% of the light that passes through the TCO layer may not be reflected back out of the microstructure. In various approaches, domed means that any corners may be rounded, which does not have to semispherical, but could be in some approaches.

Without wishing to be bound by any theory, it is believed that the concave surfaces of the dome shaped tip allows for most of the light that passes the inner surface of an outer layer to be captured. In one embodiment, concave walls may be added to increase the amount of light that is captured. Because the refractive index, as well as the higher concavity of the material increases towards the core, the light within the device itself is focused, thus causing a concentration effect and a higher current density. Moreover, the material type used has been confirmed as being able to contribute to high current density. It is also believed that the rounded edges of the dome shaped tip eliminate the accumulation of charge carriers (electrons and holes) which accumulate at sharp corners which is believed to result in reverse diode formation, and hence device failure.

In one approach, the photovoltaic device may include an array of microstructures which is arranged in a brush configuration.

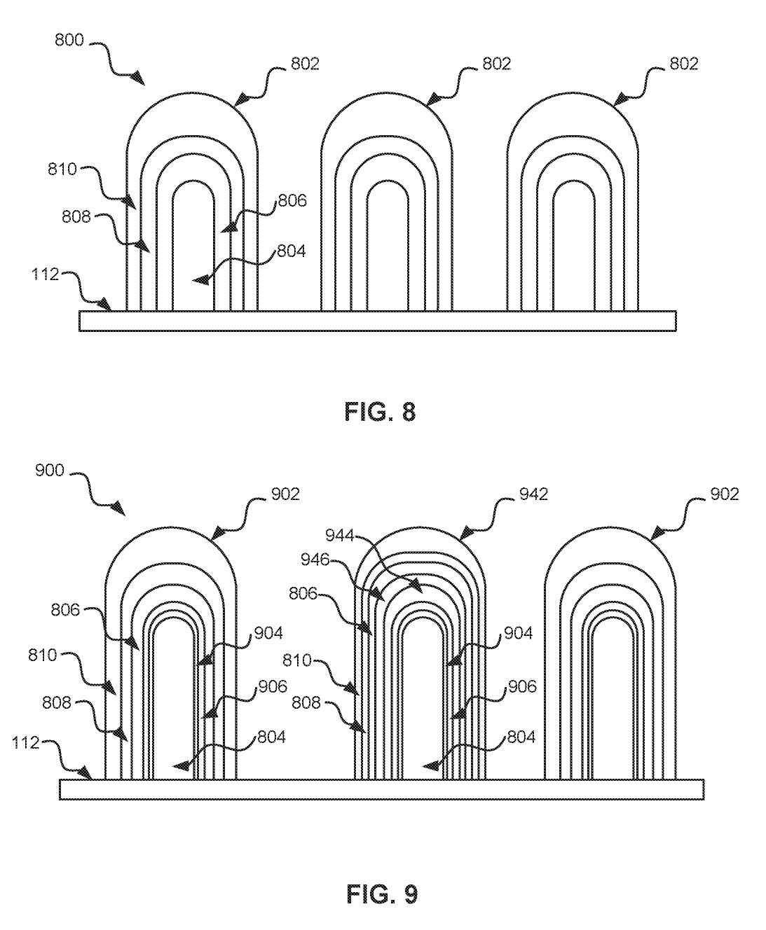

FIG. 7 is a perspective view of an exemplary solar brush 700 that may be used to implement solar cells with improved efficiency. As shown, the solar brush 700 has a substrate 702 and a plurality of microstructures 602. Moreover, in some embodiments, bristles may protrude vertically from the substrate or may protrude at angles. According to some embodiments, bristles protruding at angles may increase the amount of semiconductor materials exposed to the sun when the sun is directly overhead and may improve internal reflections.

In still another approach, the microstructures may each have at least one layer creating a single photovoltaically active junction, the at least one layer may create the single photovoltaically active junction being sandwiched between a core of the microstructure and the outer periphery. In one approach, a total material thickness between the core and the outer periphery may be between about 0.01 micron and about 10 microns. The outer periphery may be defined by an outer surface of an overlying conductive layer, and/or an inner surface (core-facing surface) of an outer conductive layer. In a preferred embodiment, the total material thicknesses may be between 0.01 and 6 microns.

FIG. 8 depicts yet another embodiment where each of the microstructures 802 of the photovoltaic device 800 includes a reflective core 804 in addition to a substrate 112. Construction of the various layers may be similar or the same as presented above in reference to FIGS. 1-7 or any other configuration as would be apparent to one skilled in the art upon reading the present disclosure.

In another embodiment, a photovoltaic device includes a first photovoltaic layer 806 over the core 804.

In an additional embodiment, a photovoltaic device, also comprising a second photovoltaic layer 808 over the first photovoltaic layer 806 thereby forming a photovoltaically active junction therewith.

In yet another embodiment, an outer conductive layer 810 is positioned over the second photovoltaic layer 808.

In yet another embodiment, an index of refraction of the outer conductive layer 810 is less than an index of refraction of the second photovoltaic layer 808, where the index of refraction of the second photovoltaic layer 808 is less than an index of refraction of the first photovoltaic layer 806. “Index of refraction” in the context of the present description is meant to be interpreted as in FIG. 1, for which the index of refraction for a given material may be calculated using Equation 1.

In still another embodiment, the core 804 (e.g., at least 80% reflective, preferably >85% reflective) can be, for example, a metallic microrod, a microrod with an overlying layer, etc. or any other core configuration described herein, or which would be obvious to one of general skill in the art upon reading the present description. In some embodiments, the photovoltaic device 800 acts as a solar concentrator.

FIG. 9 depicts one approach where the photovoltaic device 900 having a substrate 112, may include microstructures 902 each having an intervening layer 904 positioned between the core 804 and the dielectric layer 906 thereof. In several approaches, the intervening layer may be of Al, Mb, Au, etc. or any other intervening layer which would be obvious to one of general skill in the art upon reading the present description. Furthermore, one, at least two, or all of the microstructures 902 may further incorporate a second photovoltaically active junction corresponding to third 944 and fourth 946 photovoltaic layers.

In one embodiment, a photovoltaic device may incorporate microstructures which each may have layers creating at least two photovoltaically active junctions, where the at least two photovoltaically active junctions may have different, similar or the same bandgap values. In one approach, Each microstructure may have layers creating at least three photovoltaically active junctions, where the at least three photovoltaically active junctions may have different bandgap values.

In one general embodiment, a photovoltaic device, may include an array of photovoltaically active microstructures of which each may have a generally cylindrical outer periphery. Each microstructure may include a first photovoltaic layer over a core, and a second photovoltaic layer over the first photovoltaic layer thereby forming a photovoltaically active junction. An outer conductive layer may also be positioned over the second photovoltaic layer, where an index of refraction of the outer conductive layer may be less than an index of refraction of the second photovoltaic layer, and the index of refraction of the second photovoltaic layer may be less than an index of refraction of the first photovoltaic layer. Each of the microstructures being may be characterized as absorbing at least 70% of light passing through an inner surface of an outer layer thereof.

With regard to traditional solar cells, as well as some embodiments disclosed herein, one photon goes into the cell, and one electron comes out of the cell (in normal situations, in bulk material). Again, while the exact nature of quantum confinement is not completely understood, and without wishing to be bound by any particular theory, surprisingly and unexpectedly it has been found that for certain microstructures embodiments which are each physically characterized as generating multiple excitons for each one of at least some of the photons absorbed thereby.

Surprisingly and contrary to conventional wisdom, experimental testing of such approaches has displayed multiple exciton generation (MEG) per each absorbed photon, allowing for multiple electron-hole pairs to be generated per each absorbed photon. Surprisingly and unexpectedly, experiments have produced enormous amount of current density in prototype devices which far exceeds the Shockley-Queisser limit for conventional planar solar cells, which produce only one exciton. Experimental results indicate that 6 to 7 excitons are presently observable in prototypes developed. Moreover, without wishing to be bound by any theory, it is believed that up to 10 excitons may potentially be generated per photon absorbed in some embodiments. It is also believed that the light trapping effect may be responsible for this surprising phenomenon.

Moreover, a photovoltaic may further include an electrically conductive overcoat overlying the array of microstructures which may extend along the substrate between the microstructures. In various approaches, an electrically conductive overcoat may cover the top TCO with a transparent metal layer. Such metal layers may include but are not limited to gold, aluminum, etc. or any other metal layer which would be obvious to one of skill in the art upon reading to present description to reduce resistance, and improve charge collection. Still further approaches may include an electrically conductive overcoat which has a thickness of up to about 50 angstroms, where in preferred approaches, thicknesses of about 10 to about 20 angstrom. In one approach, an electrically conductive overcoat may also have a light transmission value of about 80% or more.

In one approach, a photovoltaic device according to any embodiment disclosed herein may incorporate microstructures, each of which may be physically characterized as generating multiple excitons for each one of at least some of the photons absorbed thereby.

In an additional approach, a photovoltaic device according to any embodiment disclosed herein may incorporate an electrically conductive overcoat overlying the array of microstructures and extending along the substrate between the microstructures.

Furthermore, in one embodiment, a photovoltaic device according to any approach described herein may further incorporate an electrically conductive reflective layer extending along one side of an outer surface of each microstructure in a direction parallel to a longitudinal axis of the associated microstructure; the reflective layer may extend along between 0% and about 50% of a circumference of the outer surface of the associated microstructure. In one approach, a photovoltaic device where each of the electrically conductive reflective layers may further includes a tab portion extending in a direction away from the associated microstructure; where in one specific approach, the tab may not extend to another of the electrically conductive reflective layers or another of the microstructures.

In another approach, a portion of the outer surface of a microstructure may be covered with some type of high reflectance metal which may cause a reflection of the light as well as increase conductance. Such high reflectance metals may include gold, silver, aluminum, etc. or any other metal which would be apparent to one of skill in the art upon reading the present description in various approaches. In various embodiments, such high reflectance metal may be positioned outside the TCO layer, between the TCO layer and any full-film overcoat or encapsulant, etc.

In still another approach, a high reflectance metal along may be placed along one side of the microrod and along the bottom of the same microrod. In preferred embodiments, the high reflectance metal may be a very thin layer, from about 1 to about 50 nm, preferred up to about 10 nm.

In various approaches, a high reflectance metal may be applied using any directional deposition techniques known in the art.

In one approach, a photovoltaic device may further incorporate an electrically conductive reflective layer which may extend along one side of an outer surface of each microstructure in a direction parallel to a longitudinal axis of the associated microstructure. In one approach, the reflective layer may extend along between 0% and about 50% of a circumference of the outer surface of the associated microstructure.

In a further approach, a photovoltaic device where each of the electrically conductive reflective layers may additionally include a tab portion which may extend in a direction away from the associated microstructure. In a still further approach, the tab may not extend to another of the electrically conductive reflective layers or another of the microstructures.

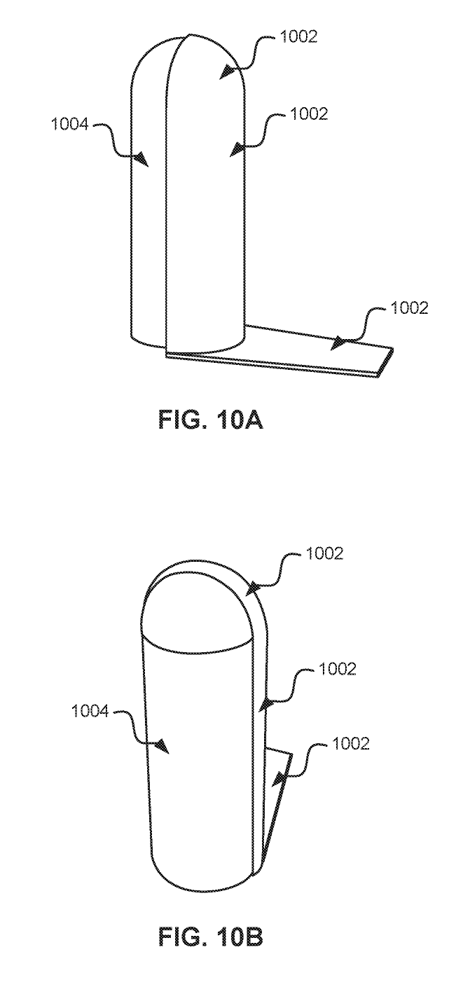

Referring to the exemplary embodiment shown in FIG. 10A-10B, a high reflectance metal portion 1002 may cover from 0 to about 180 radial degrees of a microstructure 1004 which may be in accordance with any of the microstructure configurations disclosed herein. According to the present approach, 180 radial degrees covers ½ the microrod, 90 radial degrees covers ¼, etc. In one approach, a high reflectance metal may extend up to about 5 microns in a direction parallel to and along the floor between adjacent microrods. In a preferred approach, the high reflectance metal does not extend to the adjacent microrod to avoid losses.

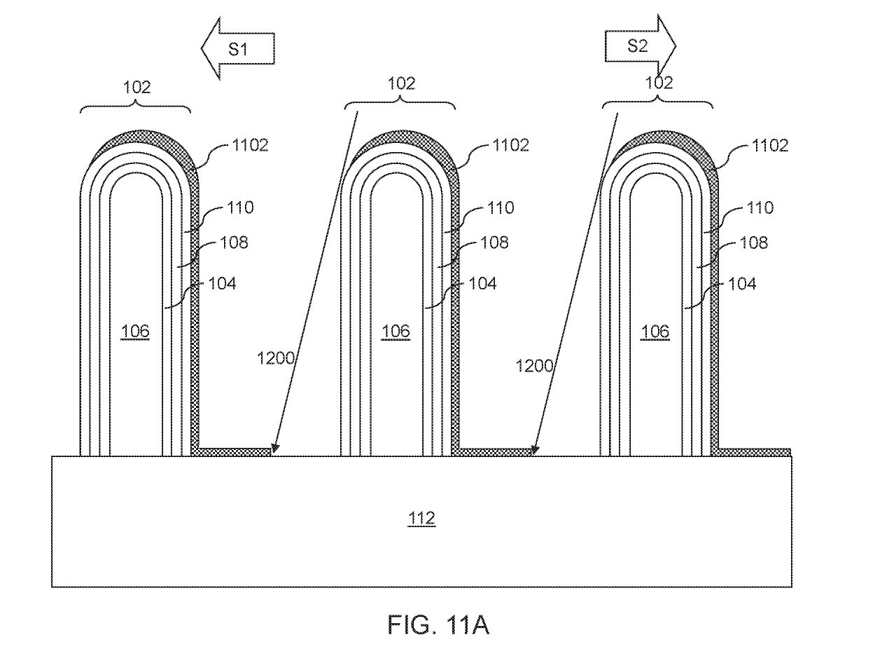

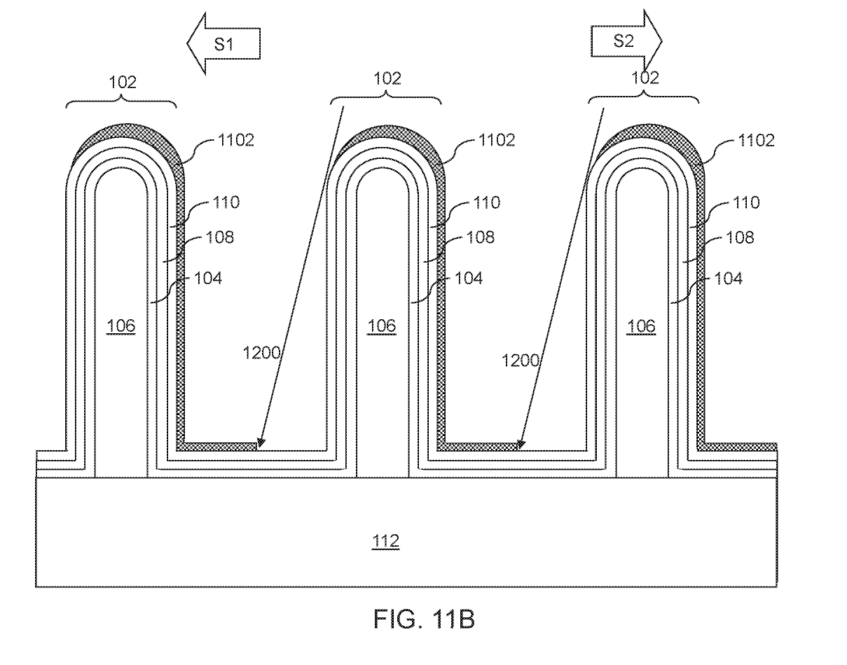

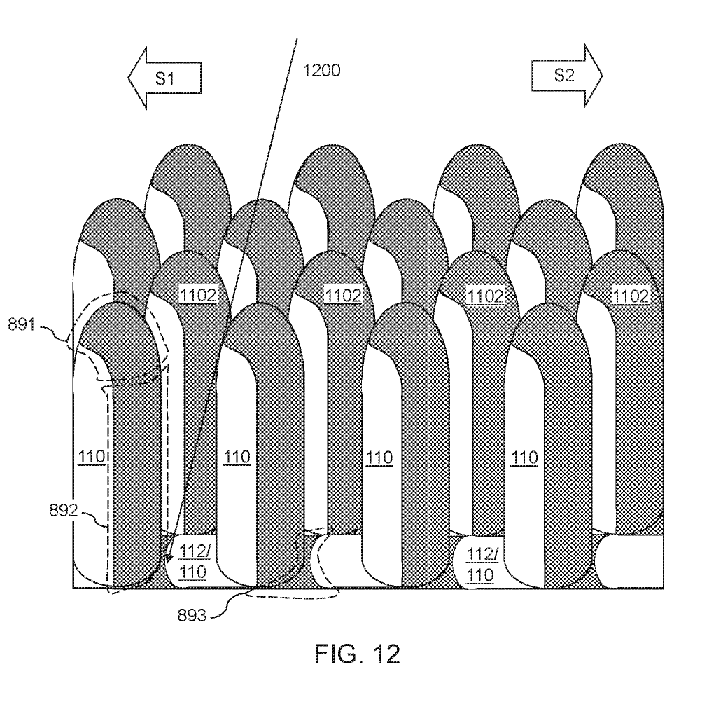

FIG. 11A shows a vertical cross-sectional view of a first exemplary structure embodying multiple instances of the photovoltaically active microstructure 102 of FIGS. 10A and 10B in an array configuration. The array of photovoltaically active microstructures 102 may be a periodic two-dimensional array, such as a hexagonal array or a rectangular array in which the photovoltaically active microstructures 102 are located at the lattice sites of a respective periodic array. Alternatively, the array of photovoltaically active microstructures 102 may be a non-periodic array in which the photovoltaically active microstructures 102 are at randomized locations with an average nearest-neighbor distance that is on par with the nearest neighbor distance of the periodic arrays described above.

Each photovoltaically active microstructure 102 may be substantially the same as any of the photovoltaically active microstructures 102 described above. As such, each of the photovoltaically active microstructure 102 in the array may include a core 106, a first photovoltaic layer 104, a second photovoltaic layer 108, and an outer conductive layer 110, and may be located on a substrate 112. Each photovoltaically active microstructure 102 may be a bristle within a solar brush, which includes an array of the photovoltaically active microstructures 102. In one embodiment, each of the photovoltaically active microstructures 102 protrudes out along a common axial from the substrate 112 to provide a brush configuration.

Each first photovoltaic layer 104 may be formed as a discrete material portion that is located over a respective core 106 and does not contact any other first photovoltaic layer 104 located over a neighboring core 106 (i.e., in an isolated form). Each second photovoltaic layer 108 may be formed as a discrete material portion that is located over a respective core and does not contact any other second photovoltaic layer 108 located over a neighboring core 106. The first photovoltaic layer 104 may be formed as discrete material portions located over a respective core and not contacting any other first photovoltaic layer 104 located over a neighboring core 106.

Optionally, the first photovoltaic layer 104 may be formed as a continuous layer including vertically protruding portions that are incorporated into the photovoltaically active microstructures 102 and a horizontal portion adjoined to each of the vertically protruding portions and overlying a top surface of the substrate 112. Optionally, the second photovoltaic layer 108 may be formed as a continuous layer including vertically protruding portions that are incorporated into the photovoltaically active microstructures 102 and a horizontal portion adjoined to each of the vertically protruding portions and overlying a top surface of the substrate 112. Optionally, the outer conductive layer 110 may be formed as a continuous layer including vertically protruding portions that are incorporated into the photovoltaically active microstructures 102 and a horizontal portion adjoined to each of the vertically protruding portions and overlying a top surface of the substrate 112. FIG. 11B illustrates a second exemplary structure in which each of the first photovoltaic layer 104, the second photovoltaic layer 108, and the outer conductive layer 110 are formed as continuous layers including a respective horizontal portion and vertically protruding portions.

Metal portions 1102 in FIGS. 10A, 10B, 11A, and 11B may be formed only on one side of each photovoltaically active microstructure 102 of the array of photovoltaically active microstructures 102. The physically exposed sidewall surfaces of the photovoltaically active microstructures 102 may face a same side, which is herein referred to as a first side S1. The metal portions 1102 may face the opposite horizontal direction, which is herein referred to as a second side S2.

As used herein, a cylindrical shape refers to any shape having a generally convex outer surface that is substantially invariant or has a taper angle less than 15 degrees along the vertical direction. It is understood that a circular cylindrical surface, an elliptical cylindrical surface, or other cylindrical surfaces of an object having a generally convex surface without vertical ridges do not have clearly defined boundaries for a side of the surface. The term “side” as used herein, therefore, refers to a portion of a generally cylindrical surface having a radial subtension angle of 180 degrees or less with respect to the axis of the object (which is defined by the generally cylindrical surface), or the general direction that such a radial portion is located at with respect to the axis of the object. The “axis” of a generally cylindrical object can be a line that connects the geometrical centers of horizontal cross-sectional shapes of the generally cylindrical object.

Thus, the exemplary structures of FIGS. 10A, 10B, 11A, and 11B are formed with inherent asymmetry between the first side S1 and the second side S2. During operation of the photovoltaic devices including the metal portions 1102, the array of photovoltaically active microstructures 102 can be oriented such that the first side S1 faces the sun or the light source, and the second side S2 faces away from the sun or the light source. The metal portions 1102 may be formed on the sidewalls of the photovoltaically active microstructures 102 that face the second side S2, and the sidewalls of the photovoltaically active microstructures 102 that face the first side S1 do not contact any metallic material. In one embodiment, the metal portions 1102 may have a variable thickness that changes with the azimuthal angle of an underlying surface and with the tilt angle of the underlying surface with respect to a vertical direction.

The asymmetry between the first side S1 and the second side S2 regarding the positioning of the metal portions 1102 may be provided by a directional deposition process. A deposition process that directs a predominant portion of atoms, particles, or clusters of metal in a beam that is tilted away from the common axial direction of the photovoltaically active microstructures 102 may be employed to form the asymmetric configuration for the metal portions 1102. As used herein, “particles” refer to a set of at least two atoms that are adjoined to one another and optionally including an additional atom of a different kind. As used herein, “clusters” refer to a set of at least two atoms of the same kind and not including any additional atom of a different kind.

For example, the direction of the beam for realizing an asymmetric deposition process is illustrated by arrows in FIGS. 11A and 11B. The tilt angle (as measured between the direction of the beam and the common axial direction of the photovoltaically active microstructures 102 which may, or may not, be perpendicular to the top surface of the substrate 110) is greater than the taper angle of the outer sidewalls of the photovoltaically active microstructures 102 in case the taper angle is non-zero. By selecting a tilt angle that is greater than the taper angle of the outer sidewalls of the photovoltaically active microstructures 102, one side of the outer sidewall of each photovoltaically active microstructure 102 is exposed to the metal beam, while the other side is no exposed to the metal beam during the directional metal deposition process.

Vertical or substantially vertical sidewalls of the photovoltaically active microstructures 102 that face the first side S1 are shielded from the directional beam of the metal during the directional metal deposition process. Thus, no metal deposition occurs on the vertical or substantially vertical sidewalls of the photovoltaically active microstructures 102 that face the first side S1. Further, shaded areas of the substrate 112 or the topmost material layer (which may be, for example, a horizontal portion of the outer conductive layer 110 as illustrated in FIG. 11B) do not accumulate any significant amount of metal thereupon during the directional metal deposition process. Each shaded area is located on the first side S1 of a respective photovoltaically active microstructure 102. The metal from the directional metal beam may be deposited in each horizontal area of the substrate 112 (or of the topmost material layer thereupon such as the outer conductive layer 110) that adjoins a bottom periphery of a photovoltaically active microstructure 102 and located on the second side S2 of the photovoltaically active microstructure 102.

FIG. 12 shows a perspective view of an exemplary pattern of the deposited metal portions 1102 induced by the directional deposition of the metal. The direction of the metal beam is illustrated by an arrow 1200.

The directionality of the metal deposition process induces variation of thickness depending on the angle between the beam of metal atoms, particles, or clusters and the local angle of the surface upon which the metal is deposited. In one embodiment, the outer sidewalls of the photovoltaically active microstructures 102 may be substantially cylindrical or tapered with a taper angle in a range from 1 degree to 10 degrees from a common axial direction of the photovoltaically active microstructures. 102. The thickness of the metal portions 1102 may be different between vertical strip portions of each metal portion 1102 and horizontal portions of the metal portions 1102 that are located over the substrate 112.

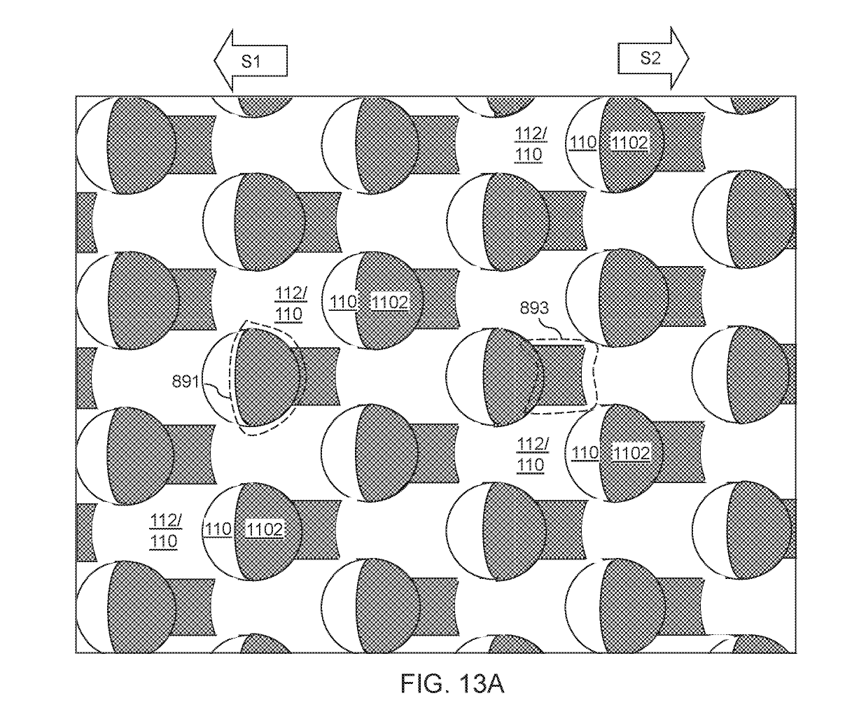

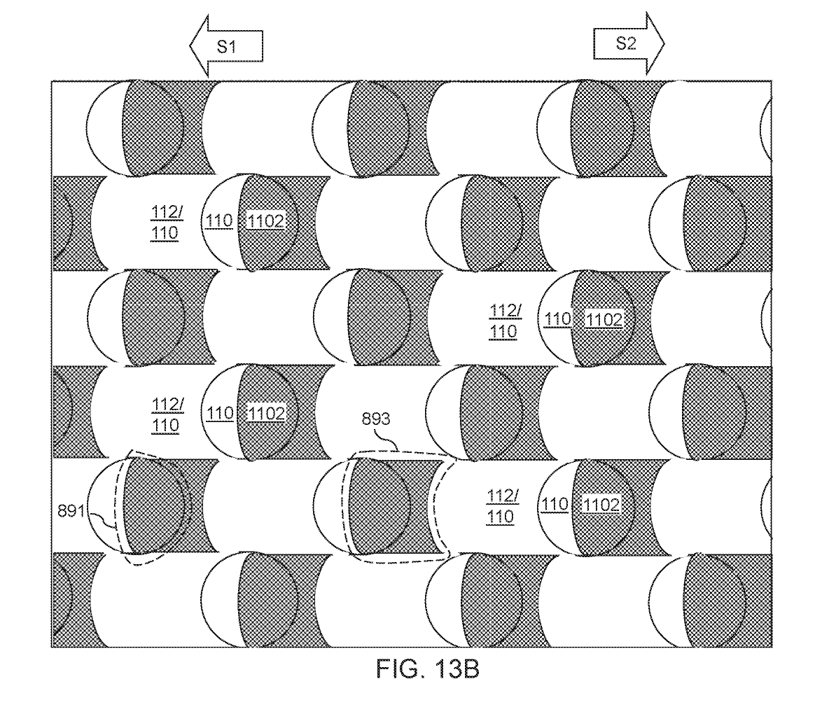

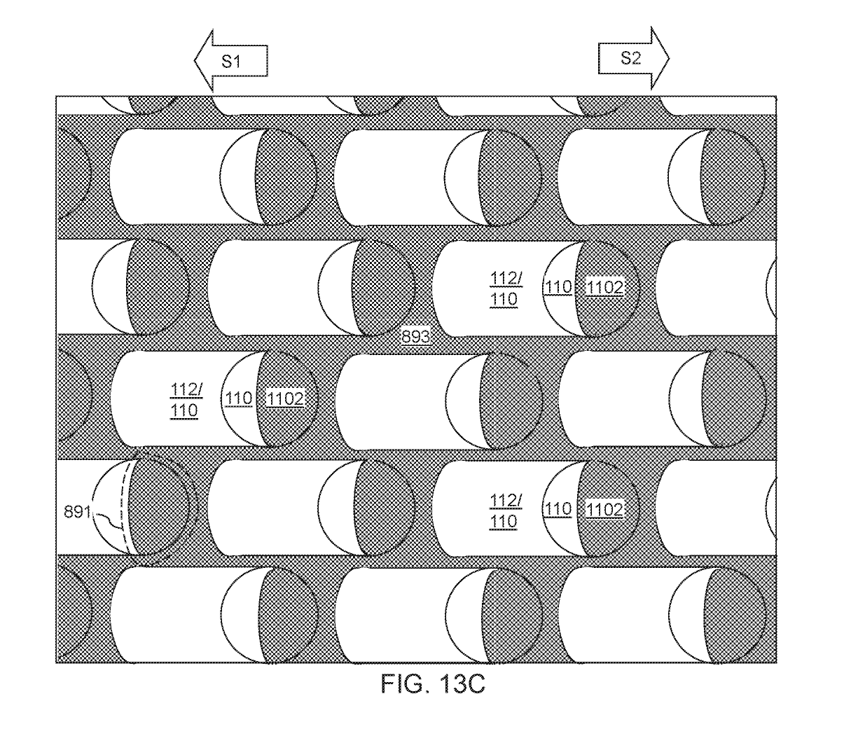

Variations in the geometrical arrangement of the photovoltaically active microstructures 102 and/or changes in the tilt angle of the metal beam during the direction metal deposition process may result in variations in the shapes of the metal portions 1102 in the vertical portions and/or in the horizontal portions overlying the substrate 112. FIGS. 13A-13C are top-down views of first, second, and third configurations of the array of photovoltaically active microstructures 102 with reflective metal portions 1102 thereupon. Each of the first, second, and third configurations is a two-dimensional periodic array of photovoltaically active microstructures 102 in which a unit cell has an area of a parallelogram. The metal portions 1102 may be formed as discrete portions as in the first and second configurations, or may be formed as a continuous metal layer that includes a continuous horizontal portion overlying the substrate 112 and adjoined to vertically extending portions (vertical strip portions) that cover sidewalls of the photovoltaically active microstructures 102 on the second side S2.

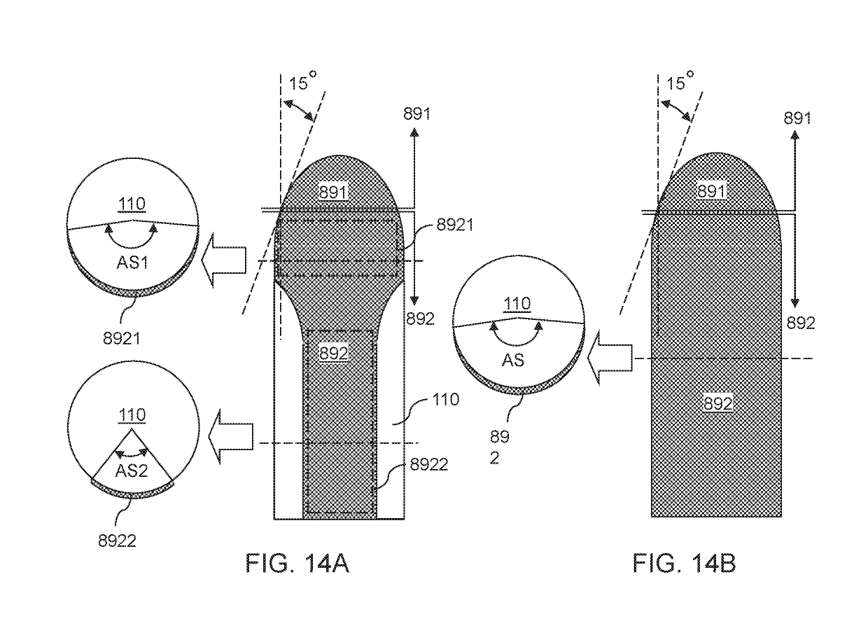

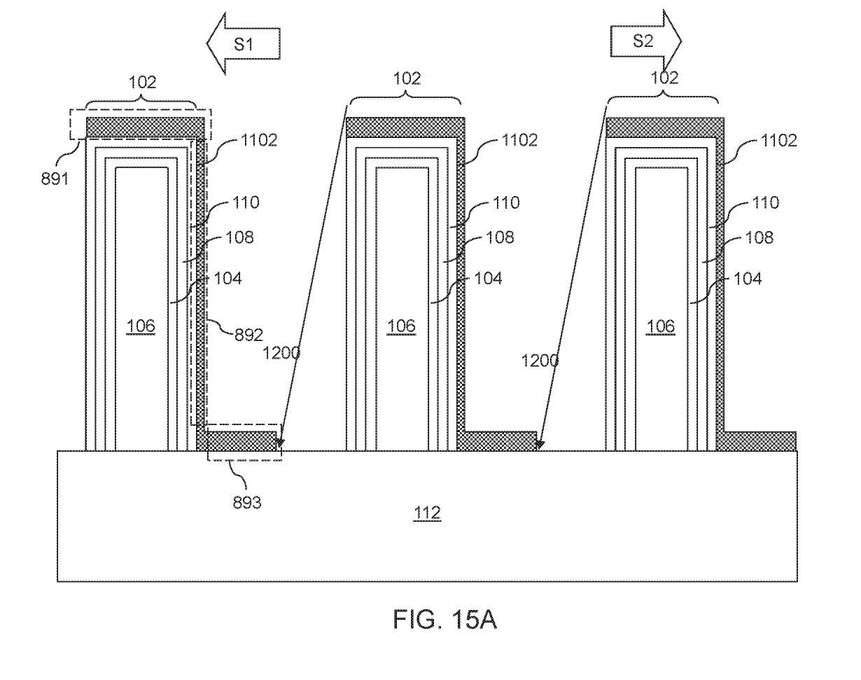

The vertical strip portion (i.e., the portion that contacts an outer sidewall of a photovoltaically active microstructure 102 on the second side S2) of each metal portion 1102 may have various shapes depending on the shapes and configuration of the photovoltaically active microstructures 102. FIG. 14A corresponds to the first configuration of FIG. 13A, and FIG. 14B corresponds to the second and third configurations of FIGS. 13B and 13C.

Referring collectively to FIGS. 11A, 11B, 12, 13A-13C, 14A, and 14B, each metal portion 1102 may comprise a metal cap portion 891 that overlies a respective photovoltaically active microstructure 102, a vertical strip portion 892 that extends from the metal cap portion 892 and contacts the outer sidewall of the respective photovoltaically active microstruture 110, and a horizontal portion 893 that adjoins a bottom region of the vertical strip portion 892 and extends parallel to a top surface of the substrate 112.

The generally cylindrical outer sidewalls of the photovoltaically active microstructures 102 may be vertical, substantially vertical, or tapered. As used herein, a “substantially vertical” surface refers to a surface that does not deviate from a vertical line by more than 1 degree, and a “tapered” surface refers to a surface that deviates from a vertical line by an angle in a range from 1 degree to 15 degrees. The boundary between the metal cap portion 891 and the vertical strip portion 892 within a metal portion 1102 is defined as the location at which the angle of the underlying surface changes from a value that does not exceed 15 degrees with respect to a vertical line to a value that exceeds 15 degrees with respect to the vertical line. A method of defining the boundary between the metal cap portion 891 and the vertical strip portion 892 in a metal portion 1102 is illustrated in FIGS. 14A and 14B.

In embodiments in which each photovoltaically active microstructure 102 comprises a rounded top surface, the tilted direction of the beam of metal atoms, particles, or clusters may be deposited in less than 100% of the rounded top surface due to shading during the directional metal deposition process. The portion of each rounded top surface of the photovoltaically active microstructures 102 facing the second side S2 may be completely covered with a respective metal cap portion 891. The portion of each rounded top surface of the photovoltaically active microstructures 102 facing the first side S1 is only partially covered with the respective metal cap portion 891 due to the curvature of the rounded top surface and the tilting of the direction of the beam of the metal atoms, particles, or clusters during the deposition process.

In one embodiment, each metal cap portion 891 may contact a fraction of the entire area of the rounded top surface of each photovoltaically active microstructure 102. In one embodiment, the fraction may be in a range from 0.60 to 0.98. In another embodiment, the fraction may be in a range from 0.70 to 0.96. In yet another embodiment, the fraction may be in a range from 0.75 to 0.94.

In one embodiment, the entirety of the area of the rounded top surface of each photovoltaically active microstructure 102 may be covered with a respective metal cap portion 891 of a metal portion 1102. For example, if the taper angle of the outer sidewalls of the photovoltaically active microstructures 10 is greater than 1 degree and less than 15 degrees, and the tilt angle of the metal beam during the directional metal deposition process is greater than the taper angle and less than 15 degrees, 100% of the top surface of each photovoltaically active microstructure 102 may be covered with a metal cap portion 891.

The metal cap portion 891 may have a non-uniform thickness distribution. Specifically, the metal cap portion 891 of each metal portion 110 may have a greater thickness in proximity to the second side S2 of the outer sidewall (on which the metal beam impinges at, or close to, normal incidence) of a respective photovoltaically active microstructure 102 than in proximity to the first side S1 of the outer sidewall (that is shaded from the metal beam) of the respective photovoltaically active microstructure 102 due to the differences in the angle of incidence.

Depending on the degree of shading of the photovoltaically active microstructures 102 by other photovoltaically active microstructures 102, the shapes of the metal portions 1102 may vary.

FIG. 14A illustrates a photovoltaically active microstructure 102 and a first exemplary reflective metal portion 1102 thereupon in a side view from the second side S2 and two horizontal cross-sectional views. In this case, the photovoltaically active microstructure 102 may be shaded on both sides below a height, which is defined by the geometry of shading. The upper portion of the vertical strip portion 892 (which is herein referred to as an upper strip portion 8921) may have a greater angular spread with respect to the axis of the photovoltaically active microstructure 102 than the lower portion of the vertical strip portion 892 (which is herein referred to as a lower strip portion 8922). In this case, each of the vertical strip portions 892 may comprise an upper strip region 8921 having a first azimuthal subtension angle AS1, and a lower strip region 8922 having a second azimuthal subtension angle AS2 that is less than the first azimuthal subtension angle AS1.

As used herein, a “subtension angle” refers to an angle by which two end portions of an object subtend as measured from a reference point. Thus, the subtension angle is the angular spread between the two end portions of the object. As used herein, an “azimuthal subtension angle” refers to the angle by which two lateral ends of an object subtend as measured from a reference point that defines the azimuthal angle, i.e., the horizontal angle or rotation. Thus, the azimuthal subtension angle is the horizontal angular spread between two lateral end portions of the object. As applied to the photovoltaically active microstructures 102, the axis of each photovoltaically active microstructure 102 defines the reference point with respect to which all azimuthal angles are defined. The azimuthal subtension angle of any sub-portion of the metal portion 1102 is thus the angular spread between two sidewalls of the sub-portion of the metal portion 1102 as measured from the axis of the photovoltaically active microstructure 102.

While the first exemplary reflective metal portion 1102 of FIG. 14A is shown to be symmetric with respect to a vertical symmetry plane that bisects the first azimuthal subtension angle AS1 and the second azimuthal subtension angle AS2, the metal portions 1102 may, or may not, have a mirror symmetry with respect to a vertical plane. For example, by selecting a metal beam direction that is not within a vertical plane including a symmetry axis of the array of photovoltaically active microstructures 102, the shading on the left side and the right side of each photovoltaically active microstructure 102 may be asymmetric. The azimuthal subtension angles (AS1, AS2) may be different even for asymmetric shading in some embodiments.

FIG. 14B illustrates a photovoltaically active microstructure 102 and a second exemplary reflective metal portion 1102 thereupon in a side view from the second side S2 and a horizontal cross-sectional view. In this case, shading of the photovoltaically active microstructure 102 by other photovoltaically active microstructures 102 may be avoided. In this case, the entirety of a vertical strip portion 892 may have the same azimuthal subtension angle AS, which may be, or close to, 180 degrees.

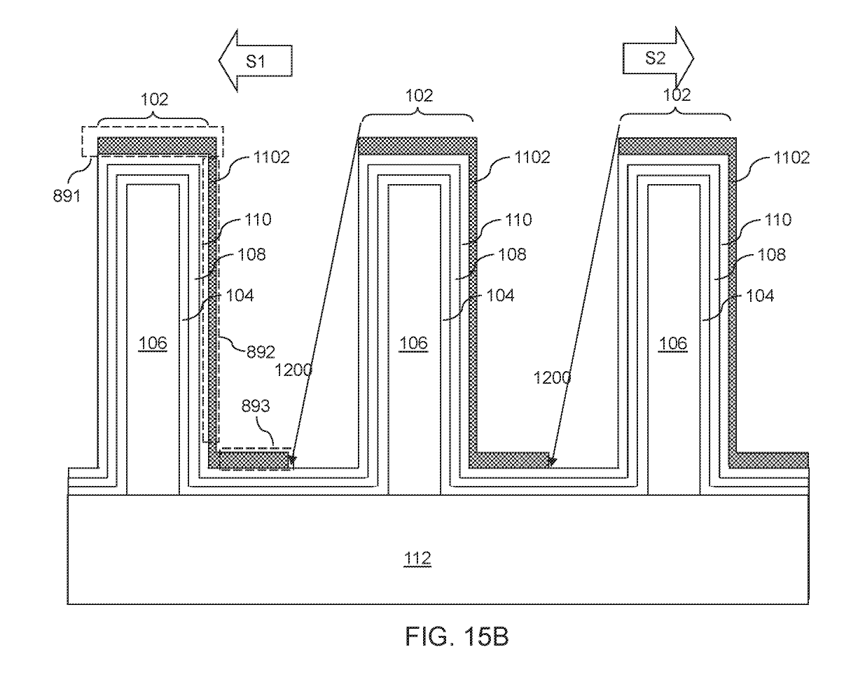

Referring to FIG. 15A, a third exemplary structure including an array of photovoltaically active microstructures 102 and reflective metal portions 1102 is shown. The third exemplary structure may be derived from the first exemplary structure of FIG. 11A by employing photovoltaically active microstructures 102 having flat top surfaces. In this, a core 106, a first photovoltaic layer 104, a second photovoltaic layer 108, and an outer conductive layer 110 within each photovoltaically active microstructure 102 may have a respective planar top surface.

Referring to FIG. 15B, a fourth exemplary structure including an array of photovoltaically active microstructures 102 and reflective metal portions 1102 is shown. The third exemplary structure may be derived from the second exemplary structure of FIG. 11B by employing photovoltaically active microstructures 102 having flat top surfaces. In this, one or more of the first photovoltaic layer 104, the second photovoltaic layer 108, and the outer conductive layer 110 may be formed as a continuous layer including vertically protruding portions that are incorporated in photovoltaically active microstructures 102. The vertically protruding portions of the first photovoltaic layer 104, the second photovoltaic layer 108, and the outer conductive layer 110 may have a respective planar top surface.

In the third and fourth exemplary structures of FIGS. 15A and 15B, each photovoltaically active microstructure 102 may comprise a flat top surface. Each metal portion 1102 may comprise a metal cap portion 891 that contact an entire area of the flat top surface. In one embodiment, each metal portion 1102 comprises a vertical strip portion 892 that contacts the outer sidewall of a respective photovoltaically active microstructure 102 and having a lesser thickness than the metal cap portion 891. In one embodiment, the metal portions 1102 may have a variable thickness that changes with the azimuthal angle of an underlying surface and with the tilt angle of the underlying surface with respect to a vertical direction. The thickness of the vertical strip portion 892 may vary azimuthally with a maximum at, or about, the direction of the second side S2 of the photovoltaically active microstruture 110.

While the present disclosure is described employing periodic two-dimensional arrays having a parallelogram-shaped unit cell, embodiments are expressly contemplated in which two-dimensional periodic arrays having different types of unit cells are employed, or in which non-periodic or randomized distribution of photovoltaically active microstructures 102 having a common axial direction is employed. Further, while photovoltaically active microstructures 102 having a circular horizontal cross-sectional shape are employed herein to describe the present disclosure, it is understood that photovoltaically active microstructures 102 having an elliptical horizontal cross-sectional shape or a polygonal horizontal cross-sectional shape may also be employed.

Optionally, an optically transparent dielectric material may be deposited over the photovoltaically active microstructures 102 and the metal portions 1102 to protect, and encapsulate, the photovoltaically active microstructures 102 and the metal portions 1102, while allowing passage of radiation (such as sunlight) therethrough. The substrate 112 may be mounted to a fixed frame, which may be mounted at a fixed location. The substrate 112 may be rotated relative to the fixed frame so that the first side S1 of each photovoltaically active microstructure 102 faces the radiation source (such as the sun) during the operation of the photovoltaic device. The deposited optically transparent dielectric material forms a transparent protective coating.

Referring collectively to FIGS. 10A, 10B, 11A, 11B, 12, 13A-13C, 14A, 14B, 15A, and 15B, various embodiments of a photovoltaic device are provided. Each of the photovoltaic devices includes an array of photovoltaically active microstructures 102 each having a generally cylindrical outer sidewall and arranged in a brush configuration over a substrate 112. A metal portion 1102 is located on a first side S1 of each outer sidewall of the photovoltaically active microstructures 1022, and a second side S2 of the each sidewall of the photovoltaically active microstructures 102 is not in physical contact with any metallic material.

In one embodiment, each photovoltaically active microstructure 102 may comprise a first photovoltaic layer 104 and a second photovoltaic layer 108 that provides a p-n junction or a p-i-n junction therebetween, and an outer conductive layer 110 laterally surrounding, and overlying, the first and second photovoltaic layers (104, 108). In one embodiment, an outer sidewall of the outer conductive layer 110 is the outer sidewall of the respective photovoltaically active microstructure 102.

In one embodiment, each of the metal portions 1102 vertically extends from a top surface of a photovoltaically active microstructure 102 to a horizontal surface above which the array of photovoltaically active microstructures 102 protrude.

In one embodiment, each of the metal portions 1102 may cover a top surface of an underlying photovoltaically active microstructure 102. In one embodiment, each of the metal portions 1102 comprises a vertical strip portion 892 that extends along an outer sidewall of a respective photovoltaically active microstruture 102 and a horizontal portion 893 that is adjoined to a bottom region of the vertical strip portion 892 and is parallel to a top surface of the substrate 112.

In some embodiment, the horizontal portion of each metal portion 1102 may contact the top surface of the substrate 112 as illustrated in FIGS. 11A and 15A. In some other embodiments, the horizontal surface may be a surface of a horizontal portion of the outer conductive layer 110 as illustrated in FIGS. 11B and 15B. For example, the outer conductive layer 110 may include vertical portions that are incorporated within the photovoltaically active microstructures 102 and a horizontal portion that is adjoined to the vertical portions of the outer conductive layer 110 and contacting horizontal portions 893 of the metal portion 1102.

In some embodiments, each vertical strip portion 892 may be located within a same azimuthal angle range (as defined by the first azimuthal subtension angle AS1 in FIG. 14A or the azimuthal subtension angle AS in FIG. 14B) with respect the axis of the photovoltaically active microstructure 102 that each metal portion 1102 contacts. In one embodiment, each vertical strip portion 892 of the metal portions 1102 may have the same azimuthal subtension angle (which may be the first azimuthal subtension angle AS1 or the azimuthal subtension angle AS) in a range from, and including, 30 degrees to, and including, 180 degrees.

In some embodiments, the vertical strip portion 892 of each metal portion 1102 may contact the outer sidewall of a respective photovoltaically active microstructure 102, and the horizontal portion 893 of each metal portion 1102 may be adjoined to the vertical strip portion 892, and may not be in physical contact with any other of the metal portions 1102 as illustrated in FIGS. 13A and 13B. In one embodiment, the horizontal portion 893 of each metal portion 1102 may extend along the same horizontal direction, which may be the direction of the second side S2. In some embodiments, each metal portion 1102 may comprise a vertical strip portion 892 contacting the outer sidewall of a respective photovoltaically active microstructure 102 and adjoined to a common horizontal metal layer 893 laterally surrounding a base of each photovoltaically active microstruture 102 as illustrated in FIG. 13C.

The photovoltaic structures of the present disclosure may be formed by providing the array of photovoltaically active microstructures 102 on the substrate 112, and by depositing a metal with directionality onto the array of photovoltaically active microstructures 102. The direction of deposition of the metal is tilted with respect to the common axial direction of the photovoltaically active microstructures 102 to enable deposition of the metal only on the second side S2 of each photovoltaically active microstructure 102, while the first side S1 of each photovoltaically active microstructure 102 is shielded from the metal beam by the photovoltaically active microstructure 102 itself. The azimuthal angle of the array of photovoltaically active microstructures 102 (i.e., the orientation of the array of photovoltaically active microstructures 102 about the vertical direction) at the time of deposition of the metal may be selected such that a continuous area of each photovoltaically active microstructure 102 is exposed to the beam of metal particles during the deposition process. Each continuous area extends from the top surface of the respective photovoltaically active microstructure 102 to a bottom periphery of the respective photovoltaically active microstructure 102. The continuous area corresponds to the area in which a respective metal portion 1102 is formed, which includes a metal cap portion 891, a vertical strip portion 892, and a horizontal portion 893.

The direction deposition of the metal may be deposited using conventional sputtering, evaporation, or ion beam sputtering methods. The deposition process is directional, i.e. has a direction along, or about, which a predominant portion of the metal atoms, particles, or clusters travel. As used herein, a predominant portion refers to more than 50%. In one embodiment, a predominant portion of the metal atoms, particles, or clusters may travel with an angular spread less than 3 degrees from a primary direction of the metal beam. The directionality of the metal beam and the tilting of the common axis of the photovoltaically active microstructures 102 from the primary direction of the metal beam cause the one-sided deposition of the metal on the photovoltaically active microstructures 102.

In one embodiment, the metal may be deposited by a physical vapor deposition process in which the predominant portion of metal particles travels along a path that is tilted from a surface normal of the substrate by an angle in a range from 5 degrees to 30 degrees. In another embodiment, an ion implantation process may be employed in lieu of the physical vapor deposition process.

In one embodiment, the metal portions 1102 may include a metal that provides both high conductivity and high reflectivity. The high conductivity of the metal can reduce the resistance of the metal portions 1102 as an electrically conductive path. The high reflectivity of the metal can reflect more of the light that impinges on the concave side (i.e., the inner sidewall of each metal portion 1102 that contacts the outer sidewall of the outer conductive layer 110) of each metal portion 1102. Suitable metals include gold, silver, aluminum, and nickel. In one embodiment, the deposition source may be a PVD sputter cathode. The cathode directionality may be controlled by aperture shields, another conventional method of sputter film manipulation.

The metal portions 1102 in various configurations may enhance the efficiency of the photovoltaic device. During operation of the photovoltaic device, light passes through the outer conductive layer 110 (which may employ a transparent conductive oxide material) to reach the photovoltaically absorbent layers, i.e., the first photovoltaic layer 104 and the second photovoltaic layer 108. The outer conductive layer 110 functions as an electrical conductor on one side of the p-n junction or the p-i-n junction. In other words, the outer conductive layer 110 is a conduit of the photogenerated electrical charges from the first and second photovoltaic layers (104, 108).

However, the transparent conductive oxide material employed for the outer conductive layer 110 has non-negligible resistance, and provides non-negligible absorption of light in the visible light spectrum.

A thick transparent conductive oxide material increases the conductivity of the outer conductive layer 110, but increases light absorption in the outer conductive layer 110. A thin transparent conductive oxide material reduces light absorption in the outer conductive layer 110, but decreases the conductivity (i.e., increases the resistivity) of the outer conductive layer 110. Thus, selection of the target thickness for the transparent conductive oxide material for the outer conductive layer 110 is a compromise between transparency and electrical conductivity.

Absorption of light in an outer conductive layer 110 employing a transparent conductive oxide material depends on the composition of the transparent conductive oxide material, the wavelength of light that passes through the transparent conductive oxide material, and the angle of incidence of the light onto the outer conductive layer 110. According to simulations performed by the inventors, when an aluminum-doped zinc oxide (ZnO:Al) material having a thickness of about 800 nm is employed for the outer conductive layer 110, and light in the wavelength range from 500 nm to 650 nm impinges on the outer conductive layer 110 with an angle of incidence between 20 degrees and 90 degrees, about 12%˜16% of the light energy that impinges onto the outer conductive layer 110 is dissipated by absorption by the transparent conductive oxide material in addition to a loss by reflection of about 6%˜30% of the light energy.

The use of the metal portions 1102 provides an additional electrically conductive path in areas that do not block the incident light. The incident light impinges onto the array of photovoltaically active microstructures 102 at an oblique angle from the first side S1. As discussed above, the angle of incidence of the impinging light with respect to the common axial direction (which may be the vertical direction) of the photovoltaically active microstructures 102 affects the output of the photovoltaic device of the present disclosure, with the peak output corresponding to an angle of incidence between 0 degrees and 90 degrees, and typically between 15 degrees and 75 degrees.

In one embodiment, the area covered by the metal cap portions 891 may be minimized by providing a pointy top portion for each of the photovoltaically active microstructures 102. Each vertical strip portion 892 of the metal portions 1102 functions as a self-aligned local conductive bus that provides a vertical electrically conductive path. By positioning (for example, by rotation) the photovoltaic device of the present disclosure such that the first side S1 faces the general direction of the incoming radiation, and the second side S2 faces the opposite direction of the incoming radiation, the metal portions 1102 do not block the incoming radiation, while providing an additional electrically conductive path.

Given the additional conductive path provided by the metal portions 1102, the thickness of the outer conductive layer 110 may be decreased significantly. For example, an outer conductive layer 110 having a thickness of about 800 nm may be replaced with a combination of an outer conductive layer 110 having a thickness in a range from 80 nm to 400 nm and a metal portion 1102 having a thickness in a range from 80 nm and 400 nm. Obviously the TCO thickness was chosen to satisfy the electrical conductivity requirements. Reduction in the thickness of the outer conductive layer 110 results in reduction of light absorption in the outer conductive layer 110, and thus, a greater fraction of the light energy may be converted into electricity employing the photovoltaic device of the present disclosure.

The photovoltaic structures of the present disclosure that include metal portions 1102 may be operated such that the first side S1 of the photovoltaic device tracks the light source, such as the sun. For example, the photovoltaic structures of the present disclosure may be rotated with movement of the sun such that the first side S1 of each outer sidewall of the photovoltaically active microstructures 102 faces from the sun, and the second side S2 of each outer sidewall of the photovoltaically active microstructures faces away from the sun during operation of the photovoltaic structure.

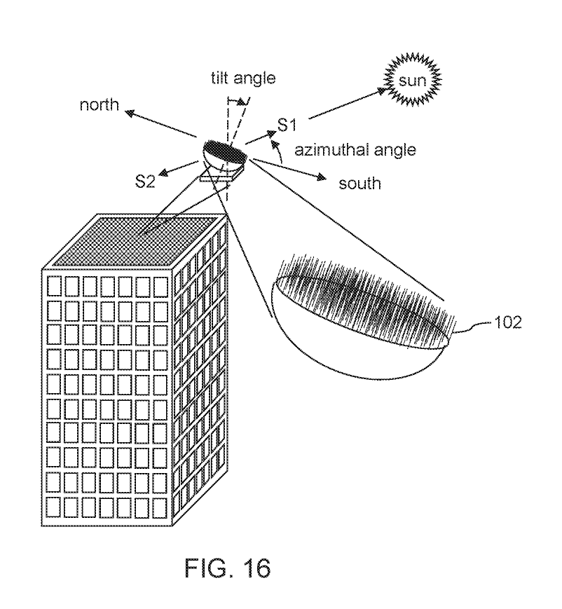

In one embodiment, a photovoltaic structure including the metal portions 1102 may be mounted on a stationary frame (which may be a building or other architectural structures as illustrated in FIG. 16). The stationary frame may remain stationary with respect to the earth. Alternatively, the photovoltaic structure including the metal portions 1102 may be mounted on a mobile frame (such as a land vehicle, a marine vehicle, an airborne vehicle, or a space vehicle).

The substrate 112 of the photovoltaic device may rotate with respect to the stationary frame or the mobile frame with the movement of the sun around an axis that is parallel to the common axial direction of the photovoltaically active microstructures 102. The rotation around the axis parallel to the common axial direction of the photovoltaically active microstructures 102 changes the azimuthal angle. The azimuthal angle can be changes such that the direction of the first side S1 coincides with the direction of the sun during the day. If the azimuthal angle of the array of photovoltaically active microstructures 102 is measured from the direction of local due south, the azimuthal angle (as measured in the clockwise direction) can be negative in the morning and positive in the afternoon.

In case the common axial direction of the photovoltaically active microstructures 102 is perpendicular to the top surface of the substrate 112, the substrate 112 may rotate in-plane such that the top surface of the substrate 112 remains within the same two-dimensional plane during the rotation. The angle between the vertical direction and the direction of the parallel axes of the photovoltaically active structures 102 is herein referred to as a tilt angle. The tilt angle may remain fixed during the day, and may be adjusted daily or seasonally to maximize the power output as the maximum solar elevation angle changes through the seasons. Alternatively, the tilt angle may be adjusted during the day to maximize the solar output. As discussed above, the maximum power output from the array of photovoltaically active microstructures 102 of the present disclosure can be provided when the minimum angle between the direction of the sun and the direction of the parallel axes of the photovoltaically active structures 102 is in a range from 5 degrees to 10 degrees.

It is noted that use of the metal portions 1102 as conductive paths is possible only because the photovoltaically active microstructures 102 include surfaces that are not parallel to the top surface of the substrate 112. Because formation of the photovoltaically active microstructures 102 provides non-illuminated sides of the photovoltaically active microstructures 102, the non-illuminated sides of the photovoltaically active microstructures 102 can be employed without hindering the path of incident light. The metal portions 1102 thus function as electrically conductive paths on the outer conductive layer 110 without blocking the incident light when suitably positioned, i.e., by azimuthally rotating the substrate such that the first side S1 of the photovoltaically active microstructures 102 faces the general direction of the incident light (as far as the azimuthal angle of the substrate 112 is concerned) with, or without, tilting the substrate 112 to change the angle of incidence of the sunlight with respect to the surface normal of the substrate 112.

In one embodiment, the tilt angle of the substrate 112 may remain fixed during the operation of the photovoltaic device of the present disclosure, and only the azimuthal angle of the substrate 112 may be adjusted. In another embodiment, the tilt angle of the substrate 112 may be adjusted to maximize the power output during the operation of the photovoltaic device of the present disclosure, in addition to the changes in the azimuthal angle of the substrate 112.

In one embodiment, the array of photovoltaically active microstructures 102 can be designed to provide peak performance (peak power output) at angles of incidence greater than 0 degrees (as measured from the surface normal of the substrate 112). A typical orientation that provides maximum power output is about 5˜10 degrees from normal incidence at solar noon. Without tilting the substrate 112 with respect to the sun, and employing an array of photovoltaically active microstructures 102 having a common axial direction that is perpendicular to the top surface of the substrate 112, only an azimuthal rotation of the substrate 112 may be employed during the operation of the photovoltaic device of the present disclosure. In this case, the minimum incidence angle of the solar ray at local noon time (at which the solar elevation angle becomes the maximum) can be in a range from 5 degrees to 10 degrees with respect to the surface normal of the substrate 112, and the range of the incidence angle may be from the minimum incidence angle to the sum of the minimum incidence angle and the range of the solar elevation angle of the day. For example, in the northern hemisphere above the Tropic of Cancer, the range of the incidence angle on the vernal equinox or on the autumnal equinox can be 90 degrees plus 23.5 degrees less the latitude.

In one embodiment, the tilt angle of the array of photovoltaically active microstructures 102 with respect a local horizontal plane may be adjusted daily to maximize the daily power output. In one embodiment, the tilt angle of the array of photovoltaically active microstructures 102 with respect the local horizontal plane may be adjusted daily such that the minimum angle of incidence (which occurs at local solar noon) remains at a predetermined value between 5 degrees and 10 degrees.

Without wishing to be bound by any theory, it is believed that such thin high reflectance metal layers may reduce resistance from top TCO layer and help increase charge collection. It is also believed that the thin high reflectance metal layers may act like a reflector of light back into the microrod, thereby further improving the light capture of the microrod.

Hard coatings such as TiN, ZrN, or HfN that have melting points around 3,000° C. may be used in various embodiments for certain layers to minimize reflectance or as a reinforcement “jacket” to increase the hardness of the microcables.

In a preferred approach, a photovoltaic device according to any embodiment disclosed herein has microstructures that may be characterized as absorbing at least 99% of light passing through the outer layer thereof inside the microstructure towards the core thereof.

Without wishing to be bound by any theory, it is believed that any one, and/or combination of reasons presented above, contributes towards a higher current density.

Moreover, experimental data, which is not meant to limit the scope of the present invention in any way, has been collected. In one illustrative embodiment, about 40 to 60 milliamps were experimentally achieved in support of the theoretical current density values which were proposed.

Furthermore, one skilled in the art would appreciate upon reading the present disclosure, the various embodiments which may incorporate any thin-film technology to design and/or construct a single junction device, multi junction device, etc.

Additional methods, configurations, etc. are presented in U.S. Pat. No. 7,847,180; U.S. patent application Ser. No. 11/466,416, filed Aug. 26, 2006; U.S. patent application Ser. No. 12/820,842, filed Jun. 22, 2010; and U.S. patent application Ser. No. 13/039,208, filed Mar. 2, 2011; and which are herein incorporated by reference. Any features disclosed in these applications may be used in conjunction with various embodiments of the present application.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A photovoltaic device, comprising:
an array of photovoltaically active microstructures each having a generally cylindrical outer sidewall and arranged in a brush configuration over a substrate, wherein:
a metal portion is located on a first side of each outer sidewall of the photovoltaically active microstructures; and
a second side of the each sidewall of the photovoltaically active microstructures is not in physical contact with any metallic material.

2. The photovoltaic device of claim 1, wherein each photovoltaically active microstructure comprises:
a first photovoltaic layer and a second photovoltaic layer that provides a p-n junction or a p-i-n junction therebetween; and
an outer conductive layer laterally surrounding, and overlying, the first and second photovoltaic layers.

3. The photovoltaic device of claim 2, wherein an outer sidewall of the outer conductive layer is the outer sidewall of the respective photovoltaically active microstructure.

4. The photovoltaic device of claim 1, wherein each of the metal portions vertically extends from a top surface of a photovoltaically active microstructure to a horizontal surface above which the array of photovoltaically active microstructures protrude.

5. The photovoltaic device of claim 1, wherein each of the metal portions covers a top surface of an underlying photovoltaically active microstructure.

6. The photovoltaic device of claim 1, wherein each of the metal portions comprises a vertical strip portion that extends along an outer sidewall of a respective photovoltaically active microstruture and a horizontal portion that is adjoined to a bottom region of the vertical strip portion and is parallel to a top surface of the substrate.

7. The photovoltaic device of claim 6, wherein the horizontal portion of each metal portion contacts the top surface of the substrate.

8. The photovoltaic device of claim 6, further comprising an outer conductive layer that includes vertical portions that are incorporated within the photovoltaically active microstructures and a horizontal portion that is adjoined to the vertical portions of the outer conductive layer and contacting horizontal portions of the metal portion.

9. The photovoltaic device of claim 1, wherein each of the metal portions includes a vertical strip portion that is located within a same azimuthal angle range with respect an axis of the photovoltaically active microstructure that each metal portion contacts.

10. The photovoltaic device of claim 9, wherein each vertical strip portion of the metal portions has a same azimuthal subtension angle in a range from, and including, 30 degrees to, and including, 180 degrees.

11. The photovoltaic device of claim 9, wherein each of the vertical strip portions comprises:
an upper strip region having a first azimuthal subtension angle; and
a lower strip region having a second azimuthal subtension angle that is less than the first azimuthal subtension angle.

12. The photovoltaic device of claim 1, wherein each metal portion comprises:
a vertical strip portion contacting the outer sidewall of a respective photovoltaically active microstructure; and
a horizontal portion adjoined to the vertical strip portion and not in physical contact with any other of the metal portions.

13. The photovoltaic device of claim 12, wherein each horizontal portion of the metal portions extends along a same horizontal direction.

14. The photovoltaic device of claim 1, wherein each metal portion comprises a vertical strip portion contacting the outer sidewall of a respective photovoltaically active microstructure and adjoined to a common horizontal metal layer laterally surrounding a base of each photovoltaically active microstruture.

15. The photovoltaic device of claim 1, wherein:
each photovoltaically active microstructure comprise a rounded top surface; and
each metal portion comprises a metal cap portion that contacts a fraction of an entire area of the rounded top surface, the fraction being in a range from 0.60 to 0.98.

16. The photovoltaic device of claim 16, wherein each metal cap portion of the metal portion has a greater thickness in proximity to the first side than in proximity to the second side.

17. The photovoltaic device of claim 1, wherein:
each photovoltaically active microstructure comprises a flat top surface; and
the metal portion comprises a metal cap portion that contact an entire area of the flat top surface.

18. The photovoltaic device of claim 17, wherein metal portion comprises a vertical strip portion that contacts the outer sidewall of a respective photovoltaically active microstructure and having a lesser thickness than the metal cap portion.

19. The photovoltaic device of claim 1, wherein each metal portion comprises:
a metal cap portion that overlies a respective photovoltaically active microstructure;
a vertical strip portion that extends from the metal cap portion and contacting the outer sidewall of the respective photovoltaically active microstruture; and
a horizontal portion that adjoins a bottom region of the vertical strip portion and extends parallel to a top surface of the substrate.

20. The photovoltaic structure of claim 1, wherein the metal portions have a variable thickness that changes with an azimuthal angle of an underlying surface and with a tilt angle of the underlying surface with respect to a vertical direction.

21. The photovoltaic structure of claim 1, wherein the outer sidewalls of the photovoltaically active microstructures are substantially cylindrical or tapered with a taper angle in a range from 1 degree to 10 degrees from a common axial direction of the photovoltaically active microstructures.

22. A method of operating the photovoltaic structure of claim 1, comprising:
providing the photovoltaic structure of claim 1; and
rotating the photovoltaic structure with movement of the sun such that the first side of each outer sidewall of the photovoltaically active microstructures faces the sun and the second side of each outer sidewall of the photovoltaically active microstructures faces away from the sun during operation of the photovoltaic structure.

23. The method of claim 22, wherein the photovoltaic structure is mounted on a stationary frame or a mobile frame with respect to which the substrate rotates with the movement of the sun around an axis that is parallel to a common axial direction of the photovoltaically active microstructures.

24. A method of forming the photovoltaic structure of claim 1, comprising:
providing the array of photovoltaically active microstructures on the substrate; and
depositing a metal with directionality onto the array of photovoltaically active microstructures, wherein a direction of deposition of the metal is tilted with respect to a common axial direction of the photovoltaically active microstructures.

25. The method of claim 24, wherein an azimuthal angle of the array of photovoltaically active microstructures at a time of deposition of the metal is selected such that a continuous area of each photovoltaically active microstructure is exposed to a beam of metal particles during a deposition process, wherein the continuous area extends from a top surface of a respective photovoltaically active microstructure to a bottom periphery of the respective photovoltaically active microstructure.

26. The method of claim 24, wherein the metal is deposited by a physical vapor deposition process in which a predominant portion of metal particles travels along a path that is tilted from a surface normal of the substrate by an angle in a range from 5 degrees to 30 degrees.
